(19) United States
(12) Patent Application Publication
(10) Pub. No.: US 2025/0219041 A1
(43) Pub. Date: Jul. 3, 2025

(54) TECHNOLOGIES FOR MEMORY AND POWER COMPONENTS EMBEDDED IN A SUBSTRATE CORE

(71) Applicant: Intel Corporation, Santa Clara, CA (US)

(72) Inventors: Whitney M. Bryks, Tempe, AZ (US); Dilan Seneviratne, Phoenix, AZ (US); Mahdi Mohammadighaleni, Phoenix, AZ (US); Yosef Kornbluth, Phoenix, AZ (US); Joshua J. Stacey, Chandler, AZ (US)

(73) Assignee: Intel Corporation, Santa Clara, CA (US)

(21) Appl. No.: 18/399,472

(22) Filed: Dec. 28, 2023

(51) Int. Cl. H01L 25/18; G11C 5/14; H10B 12/00; H10B 80/00

(52) U.S. Cl. CPC H01L 25/18; G11C 5/147; H10B 12/0385; H10B 12/0387; H10B 80/00; H10B 12/36

(57) ABSTRACT

Technologies for memory and power components embedded in a substrate core are disclosed. In one embodiment, memory components such as a high-bandwidth memory stack and power components such as deep trench capacitors are disposed in a cavity defined in a substrate core for a circuit board of an integrated circuit package, such as a processor. The components are stacked on top of each other, allowing for the stack of components to match the height of the substrate core, even when the height of the individual components is less than the height of the substrate core. Configuring the memory and power components in this manner can provide mechanical stability to the power components and substrate core and provide close access to memory and power for a semiconductor die mounted on the circuit board.

### BACKGROUND

High-power semiconductor dies require a large amount of current at a stable voltage. In order to provide a stable voltage, capacitors are often placed near the dies, such as on the same package as the dies. Capacitors near the dies can suppress power delivery noise and improve power delivery performance. Deep trench capacitors can be used as some of the capacitors to provide more stable power. In a deep trench capacitor, a three-dimensional vertical capacitor is formed by etching deep trenches in a silicon substrate.

### BRIEF DESCRIPTION OF THE DRAWINGS

FIG. 1 is an isometric view of one embodiment of a system wi33th an integrated circuit component on a circuit board with power components embedded in a substrate core.

FIG. 2 is a cross-sectional view of the system of FIG. 1.

FIGS. 3 and 4 are a flowchart of one embodiment of a method of creating one embodiment of the system of FIG. 1.

FIG. 5 is a cross-sectional view of one embodiment of a wafer for deep trench capacitors at one stage of the flowchart of FIGS. 3 and 4.

FIG. 6 is a cross-sectional view of one embodiment of a wafer for deep trench capacitors at one stage of the flowchart of FIGS. 3 and 4.

FIG. 7 is a cross-sectional view of one embodiment of a wafer for deep trench capacitors at one stage of the flowchart of FIGS. 3 and 4.

FIG. 8 is a cross-sectional view of one embodiment of a system at one stage of the flowchart of FIGS. 3 and 4.

FIG. 9 is a cross-sectional view of one embodiment of a system at one stage of the flowchart of FIGS. 3 and 4.

FIG. 10 is a cross-sectional view of one embodiment of a system at one stage of the flowchart of FIGS. 3 and 4.

FIG. 11 is a cross-sectional view of one embodiment of a system at one stage of the flowchart of FIGS. 3 and 4.

FIG. 12 is a cross-sectional view of one embodiment of a system at one stage of the flowchart of FIGS. 3 and 4.

FIG. 13 is a cross-sectional view of one embodiment of a system at one stage of the flowchart of FIGS. 3 and 4.

FIG. 14 is a cross-sectional view of one embodiment of a system at one stage of the flowchart of FIGS. 3 and 4.

FIG. 15 is a cross-sectional view of one embodiment of a system at one stage of the flowchart of FIGS. 3 and 4.

FIG. 16 is a cross-sectional view of one embodiment of a system at one stage of the flowchart of FIGS. 3 and 4.

FIG. 17 is a cross-sectional view of one embodiment of a system at one stage of the flowchart of FIGS. 3 and 4.

FIG. 18 is a partial flowchart of one embodiment of a method of creating one embodiment of the system of FIG. 1.

FIG. 19 is a cross-sectional view of one embodiment of a system at one stage of the flowchart of FIG. 18.

FIG. 20 is a cross-sectional view of one embodiment of a system at one stage of the flowchart of FIG. 18.

FIG. 21 is a cross-sectional view of one embodiment of a system at one stage of the flowchart of FIG. 18.

FIG. 22 is a cross-sectional view of one embodiment of a system at one stage of the flowchart of FIG. 18.

FIG. 23 is a cross-sectional view of one embodiment of a variation of the system of FIG. 1.

FIG. 24 is a cross-sectional view of one embodiment of a variation of the system of FIG. 1.

FIG. 25 is a cross-sectional view of one embodiment of a variation of the system of FIG. 1.

FIG. 26 is a cross-sectional view of one embodiment of a variation of the system of FIG. 1.

FIG. 27 is a cross-sectional view of one embodiment of a variation of the system of FIG. 1.

FIG. 28 is a cross-sectional view of one embodiment of a variation of the system of FIG. 1.

FIG. 29 is a cross-sectional view of one embodiment of a variation of the system of FIG. 1.

FIG. 30 is a cross-sectional view of one embodiment of a variation of the system of FIG. 1.

FIG. 31 is a cross-sectional view of one embodiment of a variation of the system of FIG. 1.

FIG. 32 is a cross-sectional view of one embodiment of a variation of the system of FIG. 1.

FIG. 33 is a cross-sectional view of one embodiment of a variation of the system of FIG. 1.

FIG. 34 is a top view of a wafer and dies that may be included in a microelectronic assembly, in accordance with any of the embodiments disclosed herein.

FIG. 35 is a cross-sectional side view of an integrated circuit device that may be included in a microelectronic assembly, in accordance with any of the embodiments disclosed herein.

FIGS. 36A-36D are perspective views of example planar, gate-all-around, and stacked gate-all-around transistors.

FIG. 37 is a cross-sectional side view of an integrated circuit device assembly that may include a microelectronic assembly, in accordance with any of the embodiments disclosed herein.

FIG. 38 is a block diagram of an example electrical device that may include a microelectronic assembly, in accordance with any of the embodiments disclosed herein.

### DETAILED DESCRIPTION

In various embodiments disclosed herein, an integrated circuit component has a circuit board with a semiconductor die disposed on its surface. The circuit board has a substrate core with a cavity defined in it. Memory and power components, such as a high-bandwidth memory stack and deep trench capacitors (DTCs), may be embedded within the cavity of the substrate core. The memory and power components can provide improved power and voltage for the semiconductor die. Embedding several components in the substrate core can provide several advantages, such as reducing real estate otherwise occupied by the components and providing a short path to the semiconductor die for memory access and power provision.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

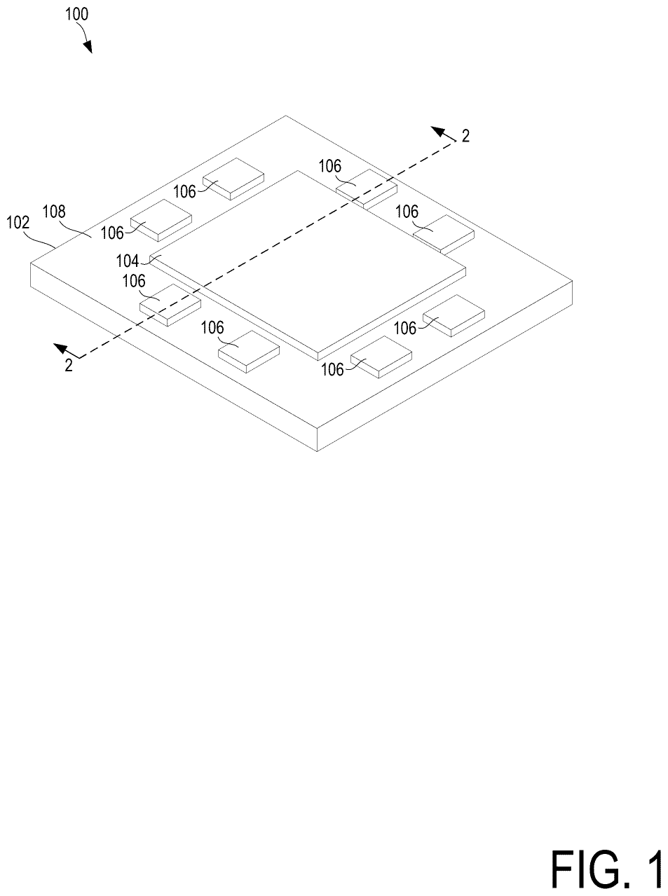

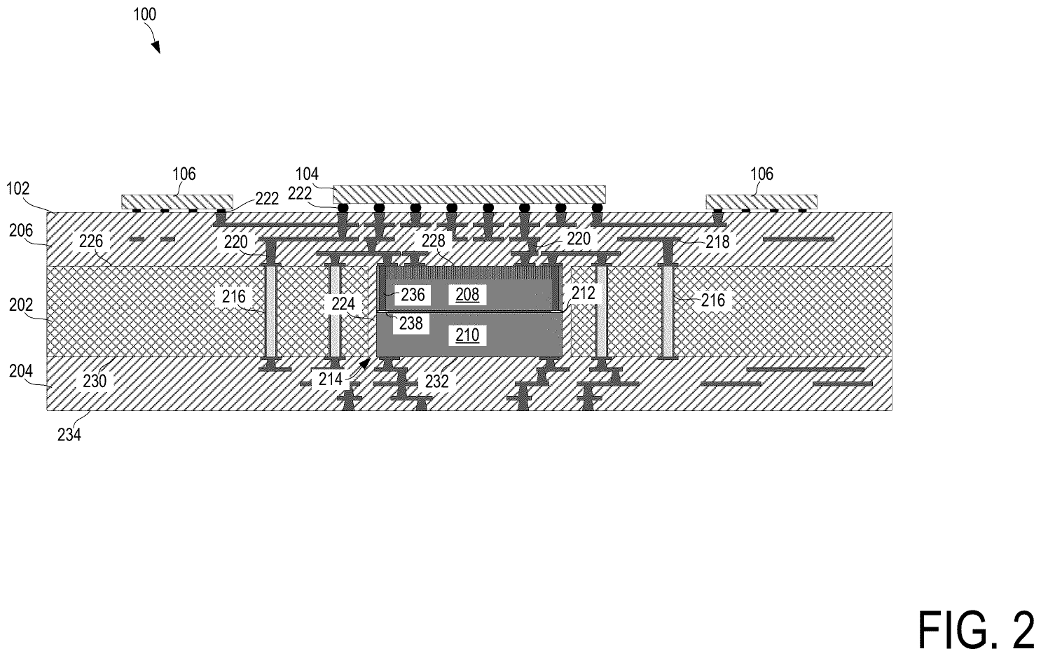

Referring now to FIGS. 1 and 2, in one embodiment, an integrated circuit component 100 includes a circuit board 102 on which one or more dies 104 are mounted. FIG. 1 shows an isometric view of the integrated circuit component 100, and FIG. 2 shows a cross-sectional view of the integrated circuit component 100. As shown in FIG. 1, a die 104 such as a processor die 104 may be disposed on the top surface 108 of the circuit board 102. In an illustrative embodiment, additional components 106, such as other semiconductor dies 106, are disposed on the top surface 108 of the circuit board 102 as well.

It should be appreciated that, as used herein, the “top side,” “bottom side,” etc., is an arbitrary designation used for clarity and does not denote a particular required orientation for manufacture or use. Although the illustrative embodiment described has the components 104, 106 placed on the “top” side of the circuit board 102, in some embodiments, those components may be placed on the “bottom” side of the circuit board 102.

The circuit board 102 includes a substrate core 202, lower build-up layers 204, and upper build-up layers 206. A cavity 214 is defined in the substrate core 202. Power component 208 and memory component 210 are disposed within the cavity 214. Power component 208 is disposed above the memory component 210. In an illustrative embodiment, a top surface 228 of the power component 208 is approximately in a plane defined by a top surface 226 of the substrate core 202, and a bottom surface 232 of the memory component 210 is approximately in a plane defined by a bottom surface 230 of the substrate core 202. For example, the top surface 228 of the power component 208 may be within 0-500 micrometers of the plane defined by top surface 226 of the substrate core 202. In an illustrative embodiment, the top surface 228 of the power component 208 may be within, e.g., 20 micrometers of the plane defined by the top surface 226 of the substrate core 202. The bottom surface 232 of the memory component 210 may be similarly positioned relative to the plane defined by the bottom surface 230 of the substrate core 202.

The power component 208 may be any suitable power component. For example, in an illustrative embodiment, the power component 208 is a DTC. Additionally or alternatively, in some embodiments, the power component 208 may be another power component, such as a magnetic inductor array 208. The DTC 208 may include one or more separate capacitors. The DTC may have any suitable capacitance, such as a capacitance of 1 femtofarad-10 microfarad and/or a capacitance density of 0.01-100 nanofarad per square millimeter. The DTC 208 may contain one capacitor or may contain more than one capacitor, such as 2-1,024. The power component 208 may form part of or be connected to a voltage regulator, such as a fully-integrated voltage regulator (FIVR).

The memory component 210 may be any suitable memory component. For example, in one embodiment, the memory component 210 is a high-bandwidth memory (HBM) component. The HBM component 210 may be a 3D stacked synchronous dynamic random-access memory (SDRAM). The memory component 210 may be a stack of an HBM controller die and several HBM dies, such as 1-16 HBM dies. The memory component 210 may be compatible with a high-bandwidth memory (HBM) standard adopted by Joint Electron Device Engineering Council (JEDEC), such as High Bandwidth Memory (HBM) DRAM standard published in document JESD235D in March 2021, High Bandwidth Memory (HBM3) DRAM standard published in document JESD238A in January 2023, and/or any other suitable past or future HBM standard adopted by JEDEC. Additionally or alternatively, in other embodiments, the memory component 210 may be dynamic random access memory (DRAM), static random access memory (SRAM), any other random access memory (xRAM), NAND memory, etc. The memory component 210 may have any suitable number of pins, such as 128-16,384. The memory component 210 may have any suitable capacity and bandwidth, such as a capacity of 1-128 gigabytes and a per-pin bandwidth of 0.25-4 gigabits.

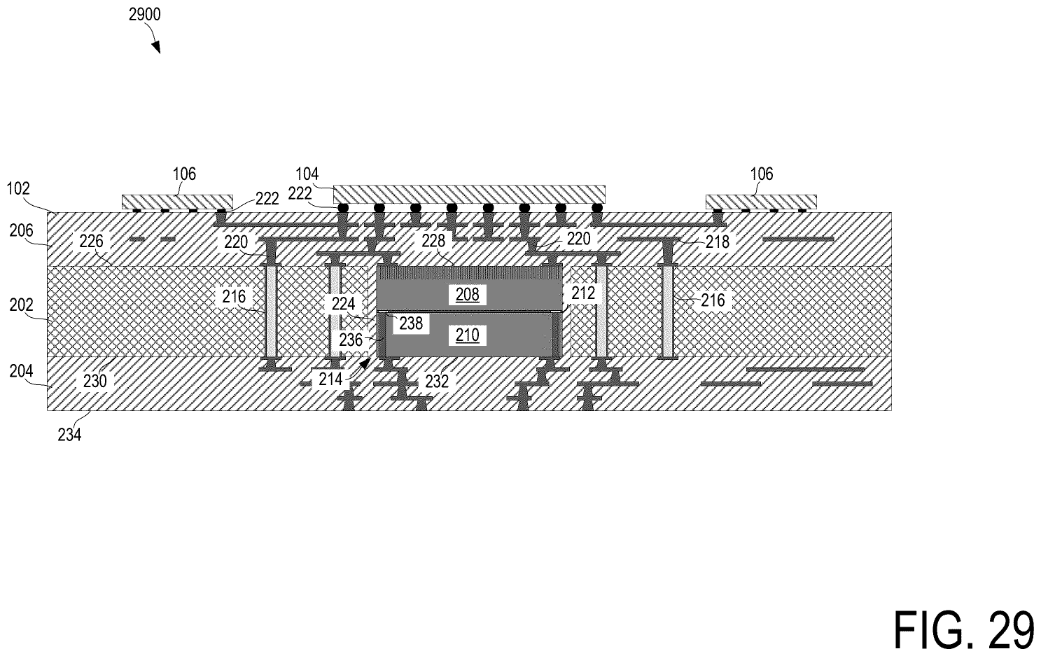

In an illustrative embodiment, through-silicon vias (TSVs) 236 may be present within one or both of the power component 208 and the memory component 210. The TSVs 236 may allow for a connection to the memory component 210 through the power component 208. The connection to the memory component 210 through the TSVs 236 may be in addition to or an alternative to connections through the lower build-up layer 204. The TSVs 236 may be made of any suitable conductive material, such as copper, tungsten, polysilicon, etc. In some embodiments, conductor 238 may connect the TSV 236 in the power component 208 to the memory component 210. The conductor 238 may be copper, solder, etc. Additionally or alternatively, the memory component 210 may be adhered to the power component 208 in a manner that does not require a separate layer of a conductor 238, such as hybrid bonding. Other embodiments of TSVs and other possible arrangements for connecting the components 208, 210 are described below in regard to FIGS. 29-33. In an illustrative embodiment, the TSVs 236 are disposed towards an edge of the power component 208 and the memory component 210. In other embodiments, the TSVs 236 may be disposed in other locations, such as closer towards the middle of the power component 208 and/or the memory component 210.

The power component 208 and memory component 210 in the cavity 214 of the substrate core 202 may provide a range of possible advantages in various embodiments. For example, the components 208, 210 may otherwise be disposed on the bottom surface 234 of the circuit board 102, taking up real estate that can instead be used for signal routing, input/output pads, solder balls, land grid array, etc. The bottom surface 234 of the circuit board 102 may also be referred to as the land side or back side of the circuit board 102. The components 208, 210 can be directly under a semiconductor die 104 they provide power to and memory for, reducing the path length between the components 208, 210 and the semiconductor die 104. The memory component 210 may be, for example, last level cache, system memory, etc., and a shorter path length between the memory component 210 and the semiconductor die 104 may improve memory latency and overall performance of the integrated circuit component 102.

Additionally, stacking the components 208, 210 can provide advantages compared to positioning a component 208, 210 in the substrate core 202. In some cases, a height of a power component 208 may be limited to, e.g., 650 micrometers, while the substrate core 202 may be taller, such as 1 millimeter. A single power component 208 disposed in a cavity 214 of the substrate core 202 may leave vertical space in the cavity 214 that would need to be filled with, e.g., mold or other filler. The mold or other filler may cause structural or mechanical issues, such as shifting of the power component 208 or other components due to, e.g., mismatch of coefficient of thermal expansion. With two components 208, 210, however, the thickness of the components 208, 210 can be reduced to, e.g., 500 millimeters, so that the total height of the components 208, 210 in the cavity 214 match the height of the substrate core 202.

In an illustrative embodiment, the circuit board 102 is a multi-layer circuit board 102 with build-up layers 204, 206 above and below the substrate core 202. The build-up layers 204, 206 may have any suitable number of layers, such as 1-10 layers each. In other embodiments, the circuit board 102 may be a single-layer circuit board 102. In an illustrative embodiment, the substrate core 202 may be an organic core, such as a fiberglass board made of glass fibers and a resin, such as FR-4. In some embodiments, the substrate core 202 may be an inorganic core 202, such as a glass core 202. The glass core 202 may be silicon oxide glass. In other embodiments, the glass core 202 may be made of any suitable material that may be crystalline, non-crystalline, amorphous, etc., such as fused silicon, borosilicate, sapphire, yttrium aluminum garnet, etc. The glass core 202 may be, e.g., aluminosilicate glass, borosilicate glass, alumino-borosilicate glass, silica, fused silica. The glass core 202 may include one or more additives, such as Al2O3, B2O3, MgO, CaO, SrO, BaO, SnO2, Na2O, K2O, SrO, P2O3, ZrO2, Li2O, Ti, and Zn. The glass core 202 may comprise silicon and oxygen, as well as any one or more of aluminum, boron, magnesium, calcium, barium, tin, sodium, potassium, strontium, phosphorus, zirconium, lithium, titanium, and zinc. The glass core 202 may include at least 20-40 percent silicon by weight, at least 20-40 percent oxygen by weight, and at least 5 percent aluminum by weight. For example, some embodiments of the glass core 202 may include, e.g., at least 20-23 percent silicon and at least 20-26 percent oxygen by weight.

The thickness of the circuit board 102 may be any suitable thickness, such as 100 micrometers to 5 millimeters. The thickness of the substrate core 202 may be any suitable thickness, such as 50 micrometers to 1.7 millimeters. The circuit board 102 can have any suitable length and width, such as 5-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 is planar. In other embodiments, the circuit board 102 may be non-planar. The cavity 214 may be any suitable size, such as a length and/or width of 1-20 millimeters.

In an illustrative embodiment, the die 104 above the components 208, 210 is a processor die and other dies 106 may be memory dies communicatively coupled to the processor die 104. In other embodiments, the die 104 and/or the dies 106 may be any suitable die, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104, 106 may be connected to contact pads or vias 220 on the circuit board 102 through solder balls 222.

As referenced above, the power component 208 may be any suitable power component, such as DTC 208 and/or magnetic inductor array 208. In an illustrative embodiment, the DTC 208 is a silicon die that include an array of trenches, such as trenches that are 0.1-100 micrometers deep. The trenches may have a pitch of, e.g., 0.2-5 micrometers. The DTC 208 may include any suitable number of trenches, such as 1-10,000. One electrode for a capacitor may be conformal with the trenches, with a dielectric material on top of the electrode, and the other electrode on top of the dielectric material. The electrodes for the capacitor may be coupled to traces 218 or pads 218 defined in the build-up layers 204, 206. The DTC 208 may be connected to the die 104, the dies 106, a component connected to the circuit board 102, etc., through various connections in the integrated circuit component 100, such as traces 218, vias 220, through holes 216, etc. The components 208, 210 may have any suitable dimensions, such as a height of 25 micrometers to 650 micrometers and a length and/or width of 1-20 millimeters.

The components 208, 210 may be attached together in any suitable manner, such as by using an adhesive 212, such as die attach film 212. Additionally or alternatively, the components 208, 210 may be attached together using, e.g., glue epoxy, bump bonding, hybrid bonding, fusion bonding, thermocompression bonding, wafer on wafer bonding, wafer-on-wafer hybrid bonding, solder with underfill, and/or the like.

The volume of the cavity 214 that is not taken up by the components 208, 210 may be filled with any suitable filler material 224. For example, the filler material 224 may be prepreg, Ajinomoto build-up film (ABF), photoimageable dielectric, an inorganic dielectric material, an organic dielectric material, an oxide, a nitride, silicon dioxide, silicon nitride, polymer, epoxy, polyimide, polymer composites with inorganic fillers, and/or the like. The filler material 224 may be applied using any suitable approach, such as compression molding, vacuum lamination, hot press, chemical vapor deposition, physical vapor deposition, and/or the like.

In an illustrative embodiment, plated through holes 216 extend from the top surface 226 of the substrate core 202 to the bottom surface 230 of the substrate core 202. The through holds 216 may transport power and/or data signals through the substrate core 202.

The circuit board 102 includes traces 218 and vias 220. The traces 218 and vias 220 may be made of any suitable conductive material, such as copper or aluminum.

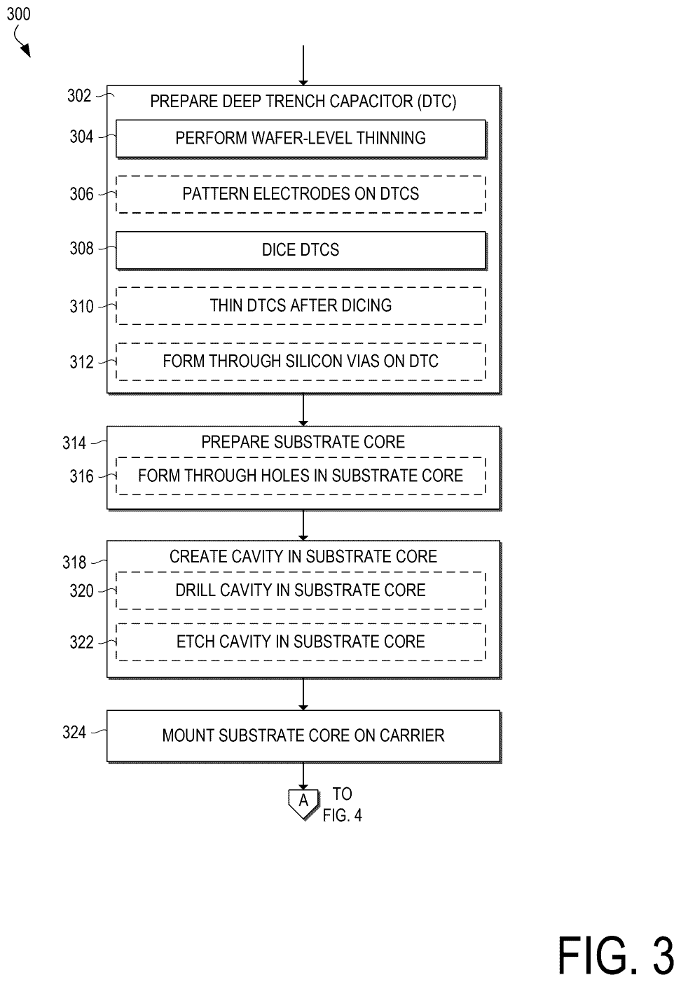

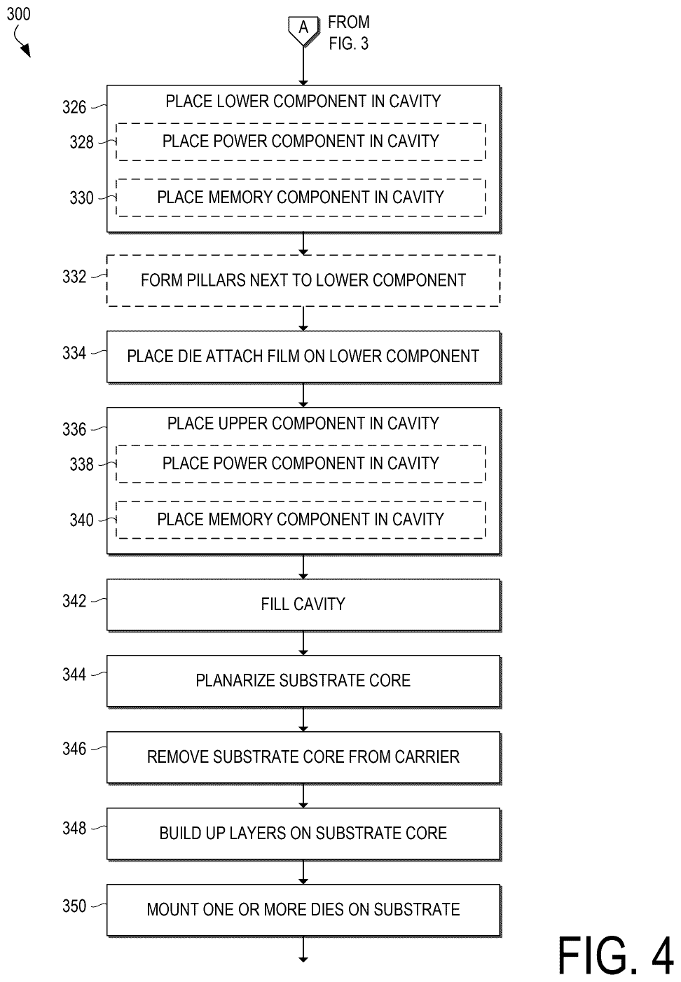

Referring now to FIGS. 3 and 4, in one embodiment, a flowchart for a method 300 for creating the integrated circuit component 100 is shown. The method 300 may be executed by a technician and/or by one or more automated machines. In some embodiments, one or more machines may be programmed to do some or all of the steps of the method 300. Such a machine may include, e.g., a memory, a processor, data storage, etc. The memory and/or data storage may store instructions that, when executed by the machine, cause the machine to perform some or all of the steps of the method 300. The method 300 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, 3D photolithography, screen printing, ink jet printing, etc. It should be appreciated that the method 300 is merely one embodiment of a method to create one embodiment of a system and other methods may be used to create any suitable embodiment of the system. In some embodiments, steps of the method 300 may be performed in a different order than that shown in the flowchart.

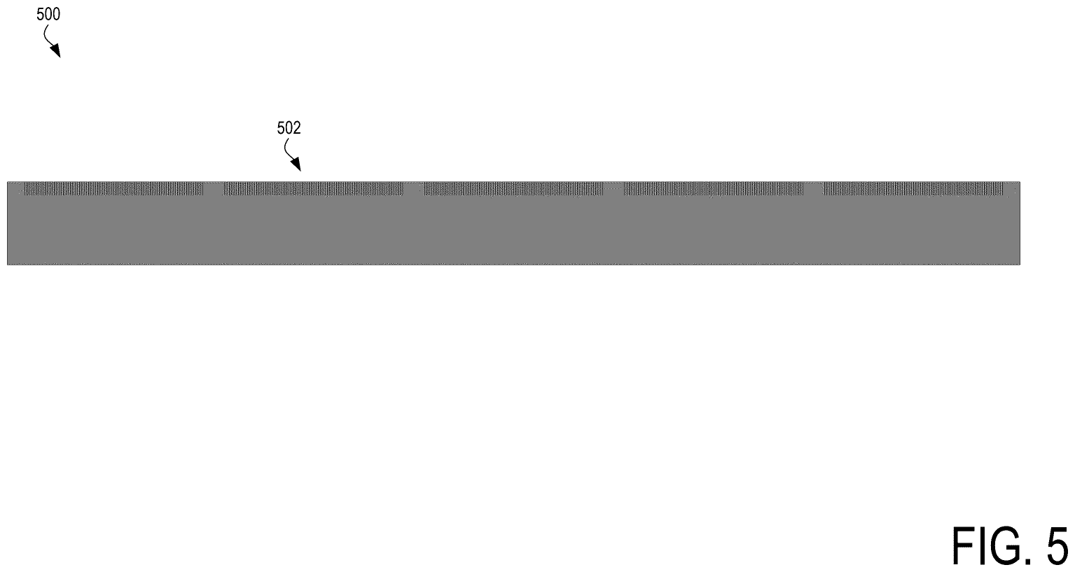

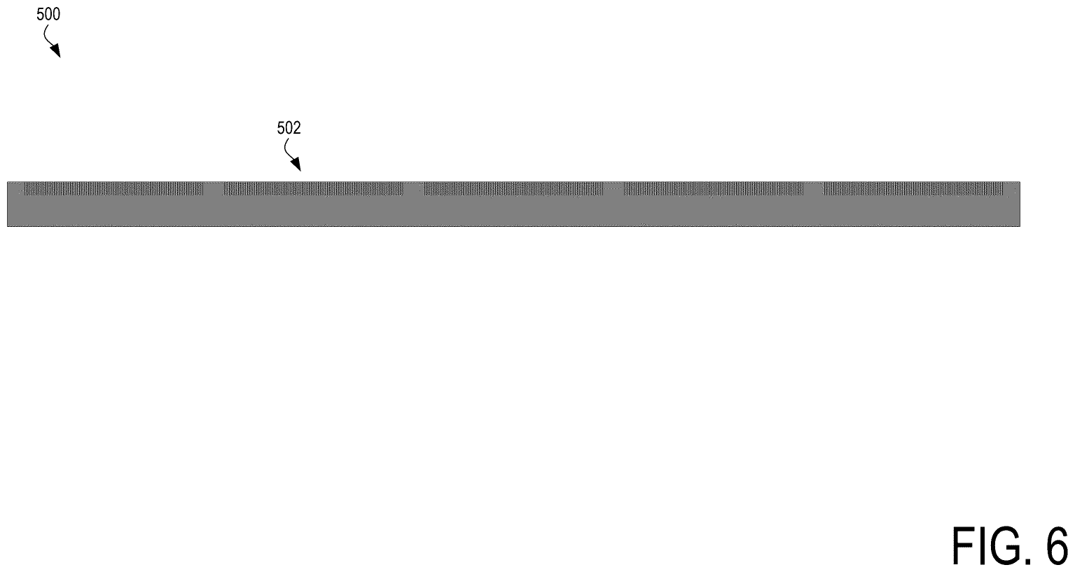

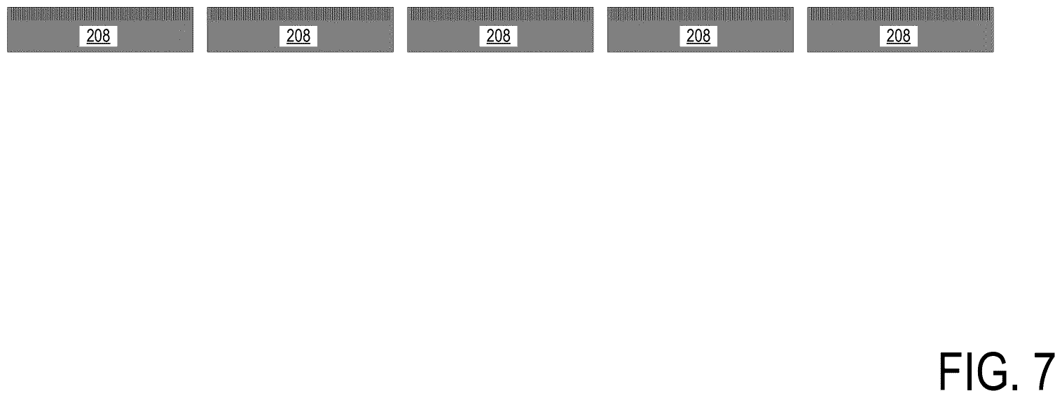

The method 300 begins in block 302, in which one or more DTCs 208 are prepared. In an illustrative embodiment, a wafer 500 with multiple arrays of deep trenches 502 is fabricated. A cross-section of part of such a wafer 500 is shown in FIG. 5. In some embodiments, wafer-level thinning may be performed in block 304, leading to a thinner wafer 500, as shown in FIG. 6. Additionally or alternatively, in other embodiments, the DTCs 208 may be thinned after dicing or the DTCs 208 may not be thinned. In block 306, in some embodiments, electrodes may be patterned on the DTCs 208. Additionally or alternatively, in some embodiments, electrodes may be patterned on the DTCs 208 in another step of the manufacturing process, such as when forming the build-up layers 204, 206. In block 308, the wafer 500 is diced to form DTCs 208, as shown in FIG. 7. In some embodiments, in block 310, the DTCs 208 may be thinned after dicing. In some embodiments, in block 312, through-silicon vias 236 may be formed on the DTC 208 at the wafer level. In other embodiments, the DTCs 208 may have through-silicon vias 236 formed at a later time, as described below. In some embodiments, the memory component 210. At this stage, in some embodiments, memory components 210 may be mounted on the DTCs 208, such as by using die attach film 212. The memory components 210 may be mounted on the DTCs 208 at the die level or the wafer level. For example, part or all of the memory components 210 may be diced and mounted on a wafer of DTCs 208, DTCs 208 may be diced and mounted on a wafer of part or all of several memory components 210, part or all of the memory components 210 may be diced and mounted on diced DTCs 208, and/or a wafer of part or all of the memory components 210 may be mounted on a wafer of DTCs 208. In some embodiments, pre-fabricating the stack of components 208, 210 may allow for testing of the stack of components 208, 210 before integration into the substrate core 202, increasing yield and reducing cost.

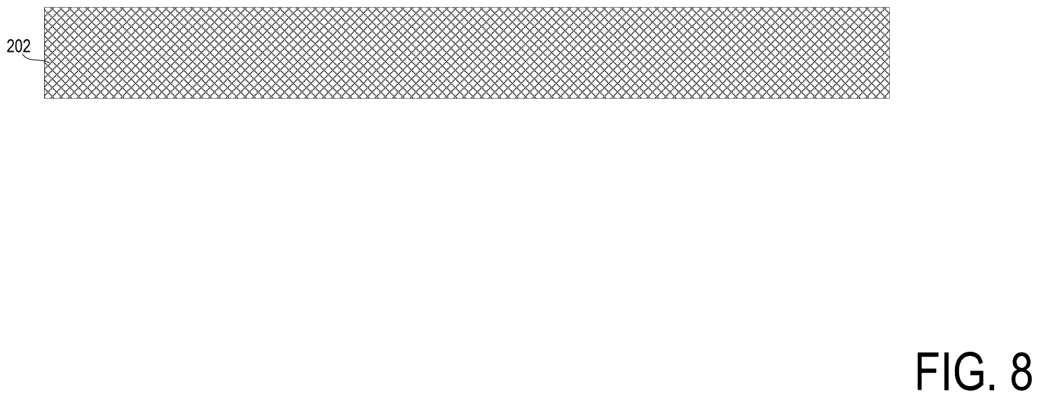

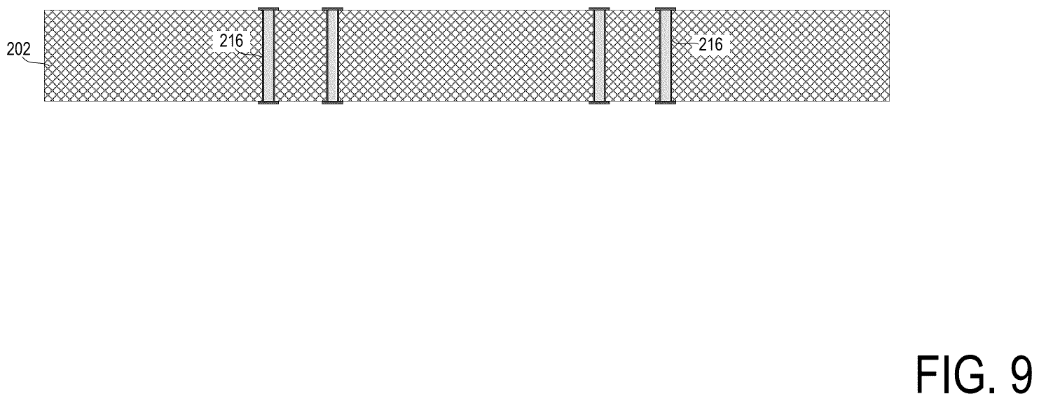

In block 314, a substrate core 202 is prepared, such as by dicing, polishing, etc., as shown in FIG. 8. In some embodiments, in block 316, through holes 216 are formed in the substrate core 202, as shown in FIG. 9.

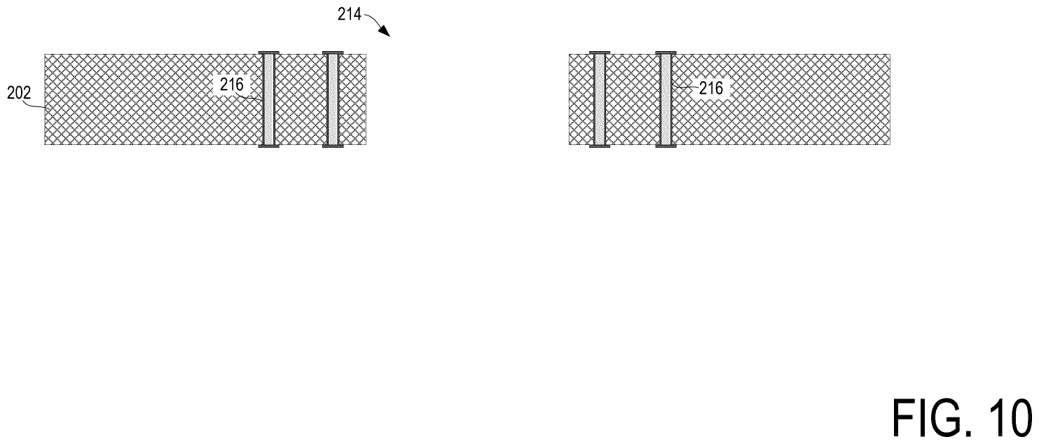

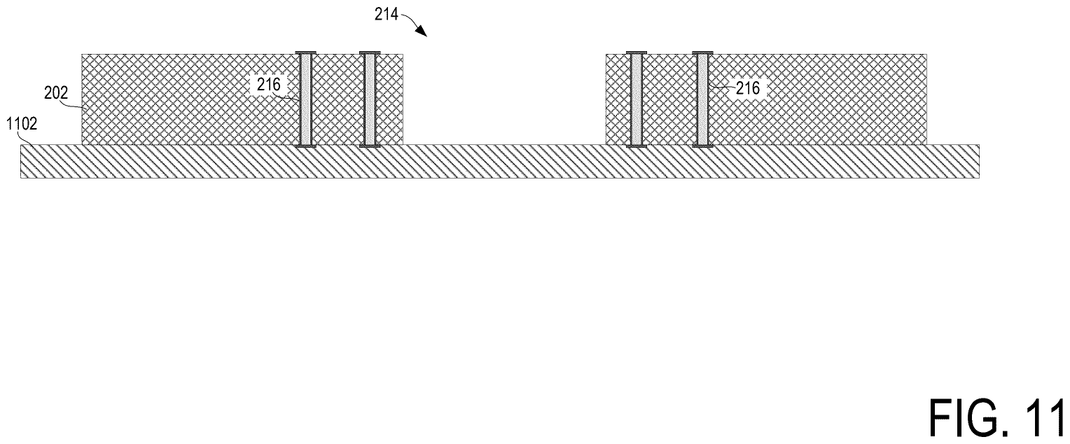

In block 318, a cavity 214 is formed in the substrate core 202, as shown in FIG. 10. The cavity 214 may be formed in any suitable manner. For example, in some embodiments, the cavity 214 may be formed by drilling out the cavity 214 in block 320, such as by using a mechanical or laser drill. In other embodiments, the cavity 214 may be etched away in block 322. In block 324, the substrate core 202 is mounted on a carrier 1102, as shown in FIG. 11. The carrier 1102 may be, e.g., a silicon or other substrate, a glass substrate, a tape material, and/or the like.

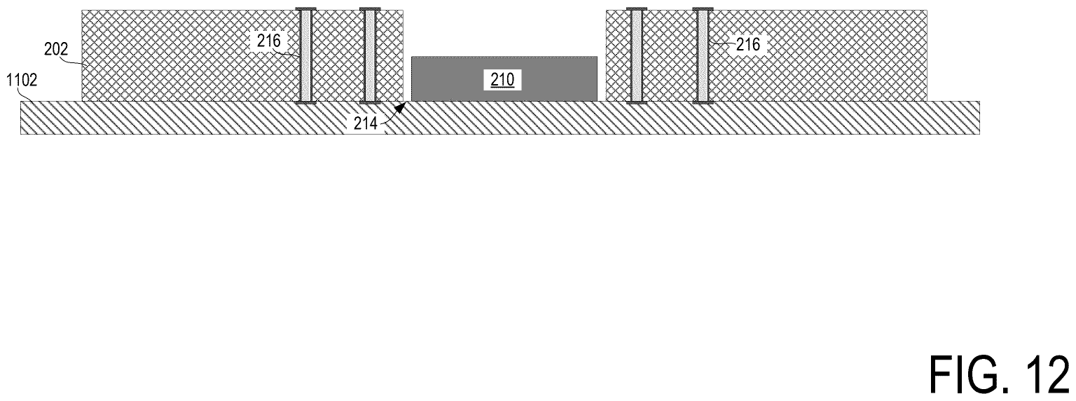

Referring now to FIG. 4, in block 326, the lower component 208, 210 is placed in the cavity 214, as shown in FIG. 12. The lower component may be a power component 208 or a memory component 210, depending on the embodiment. In some embodiments, a power component 208, such as a DTC 208 or a magnetic inductor array 208, is placed in block 328. In other embodiments, a memory component 210, such as an HBM stack 210 or DRAM die 210, may be placed in block 330.

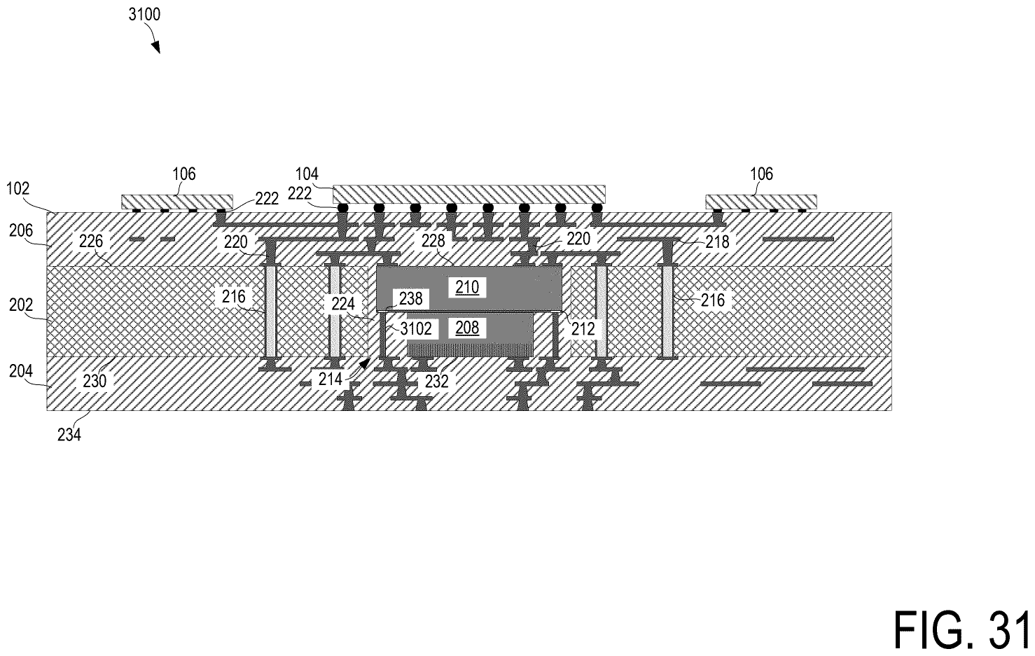

In block 332, in some embodiments, pillars 3102 may be formed next to the lower component 208, 210. FIG. 31 described below shows an embodiment with pillars 3102. In some embodiments, the pillars 3102 may be used in addition to or in place of through-silicon vias 236. Pillars 3102 may be formed by, e.g., applying a thick layer of photoresist, etching a deep hole in the photoresist, forming the pillars 3102 using, e.g., electroless plating and/or electroplating, removing the photoresist, and filling up the cavity 214 around the pillars 3102. The pillars 3102 may be made of copper or other suitable material.

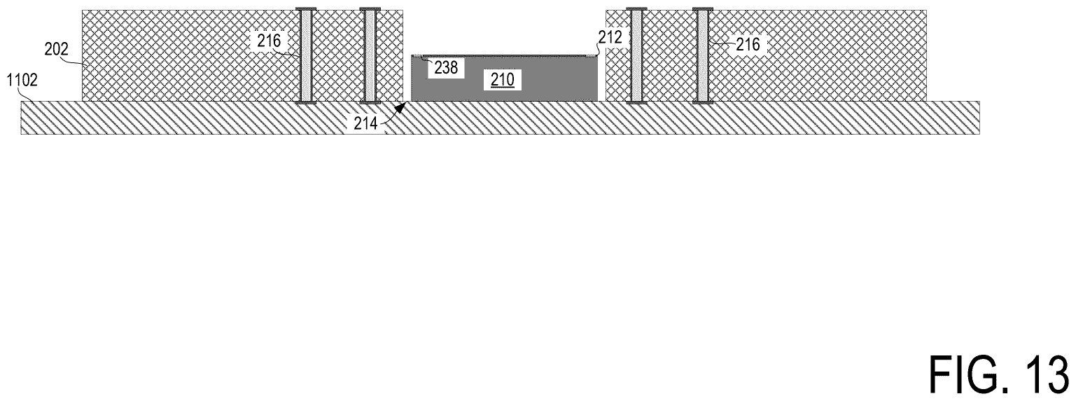

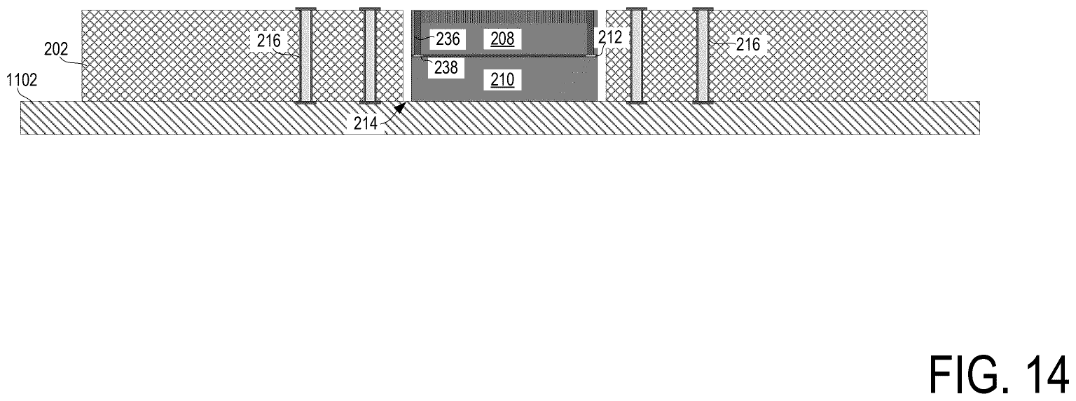

In block 334, a die attach film 212 is placed on the lower component 208, 210, as shown in FIG. 13. In other embodiments, the components 208, 210 may joined together in another manner, such as by using glue epoxy, bump bonding, hybrid bonding, fusion bonding, thermocompression bonding, etc. In block 336, an upper component 208, 210 is placed in the cavity 214, as shown in FIG. 14. In some embodiments, a power component 208, such as a DTC 208 or a magnetic inductor array 208, is placed in block 338. In other embodiments, a memory component 210, such as an HBM stack 210 or DRAM die 210, may be placed in block 340. In an illustrative embodiment, through-silicon vias 236 may be added to the power component 208 after it is mounted on the memory component 210. In other embodiments, the TSVs 236 may be added to the power component 208 before it is mounted on the memory component 210.

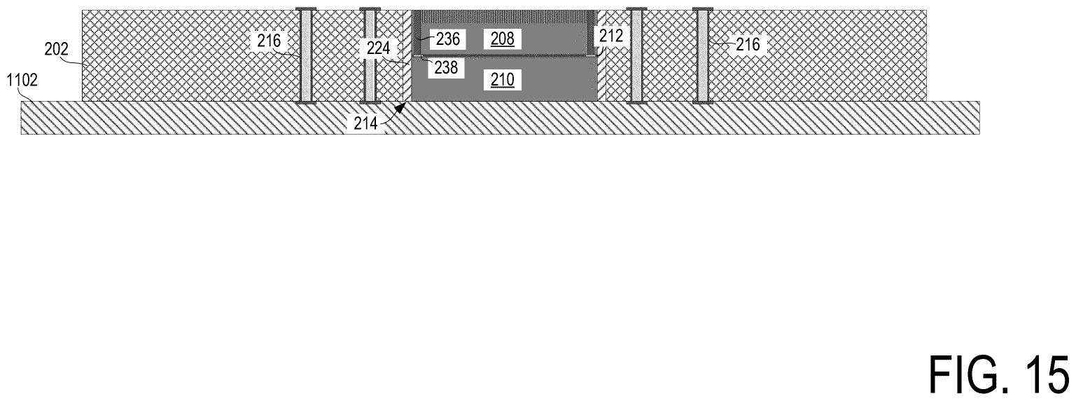

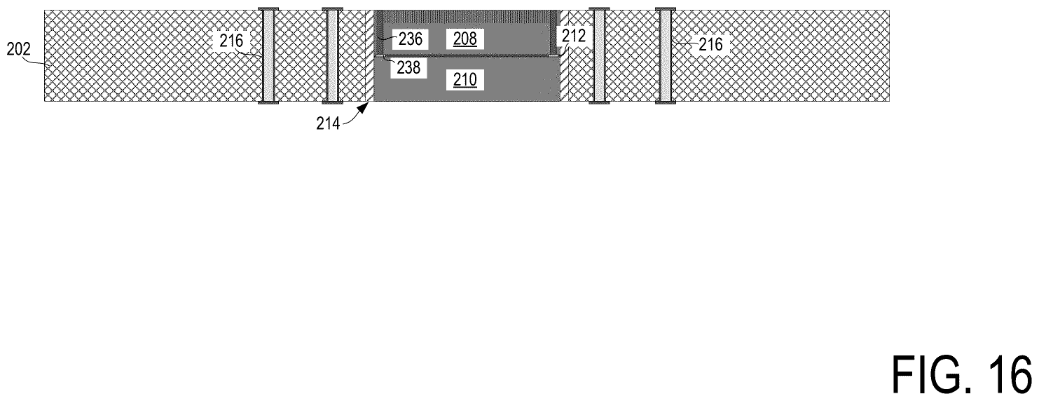

In block 342, the cavity 214 is filled with filler material 224, such as prepreg, ABF, photoimageable dielectric, etc. The filler material 224 may be applied using any suitable approach, such as compression molding, vacuum lamination, hot press, chemical vapor deposition, physical vapor deposition, and/or the like. In block 344, the substrate core 202 is planarized, as shown in FIG. 15. In block 346, the substrate core 202 is removed from the carrier 1102, as shown in FIG. 16.

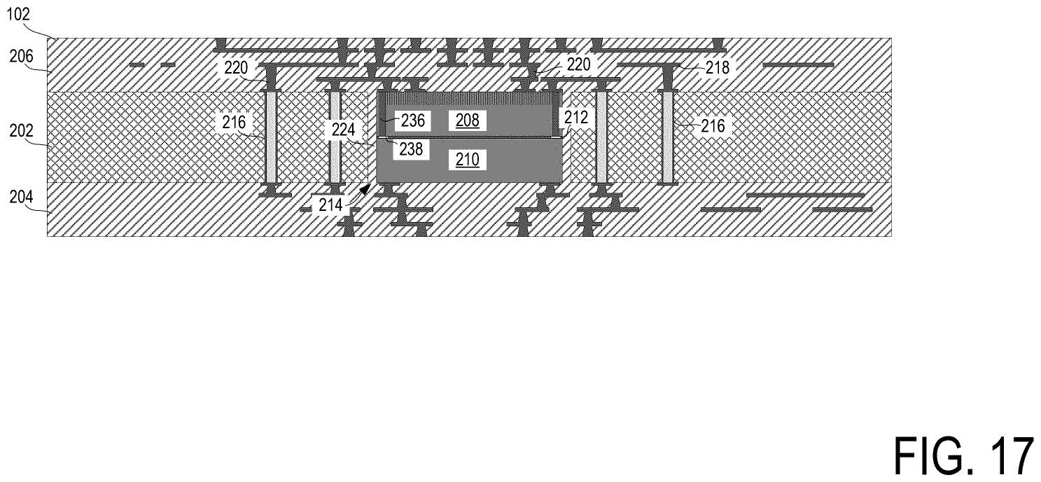

In block 348, build-up layers 204, 206 are built up on the substrate core 202, as shown in FIG. 17. The build-up layers 204, 206 may be created using any suitable set of techniques, such as electroplating, electroless plating, photolithography, etching, etc. In block 350, one or more dies 104, 106 are mounted on the substrate, completing the integrated circuit component 100, as shown in FIG. 2.

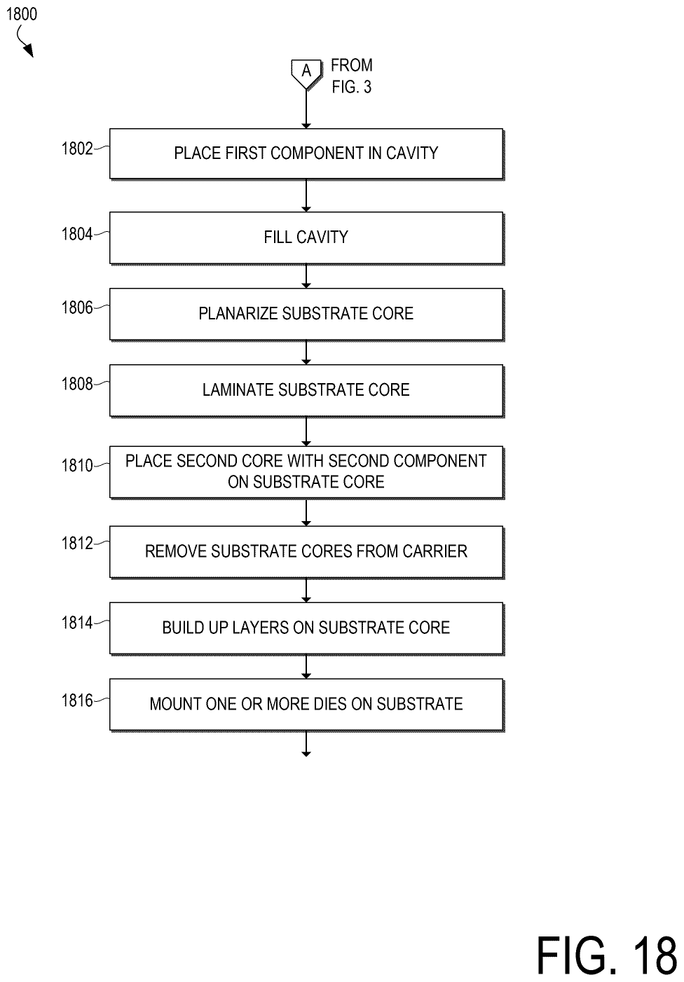

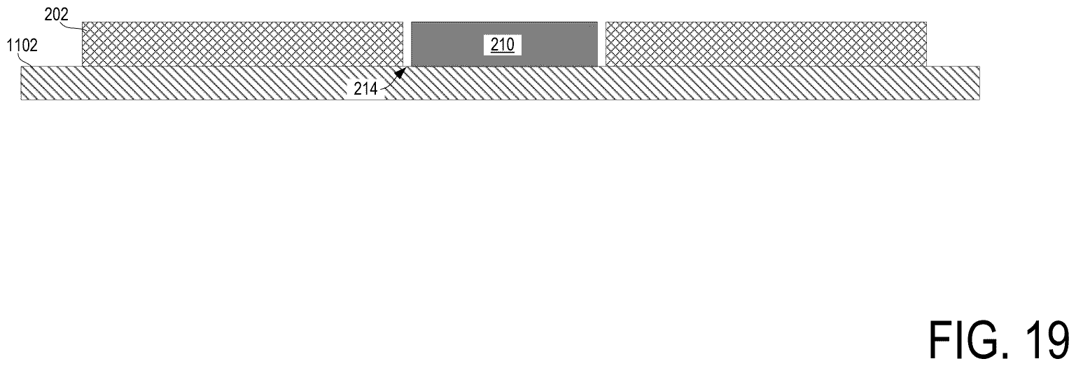

Referring now to FIG. 18, in one embodiment, a flowchart for an alternate method 1800 for creating a substrate core for the integrated circuit component 100 is shown. The method 1800 may begin with blocks 302-324 of the method 300 described above. After block 324, the method 1800 proceeds to block 1802, in which the memory component 210 is placed in the cavity 214, as shown in FIG. 19. In the embodiment depicted in FIG. 19, the memory component 210 has about the same height as the substrate core 202.

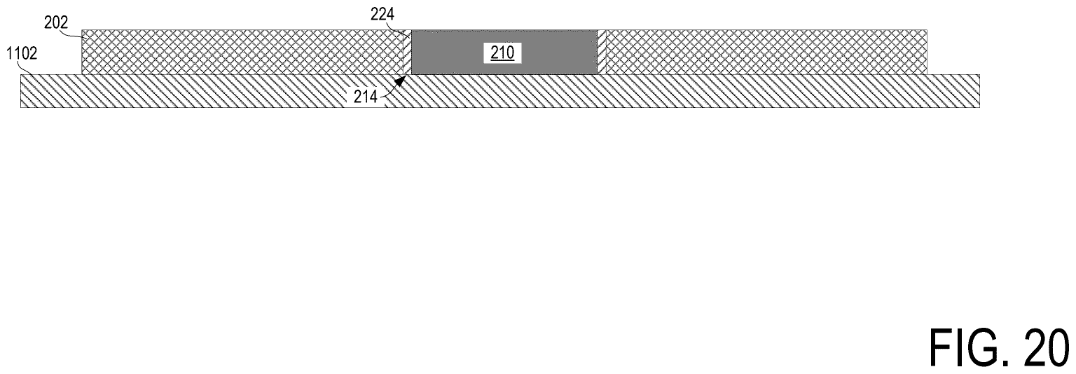

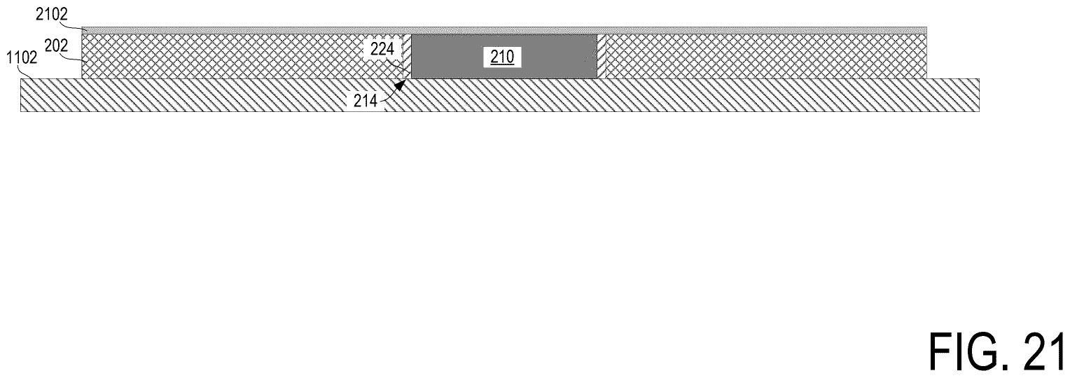

In block 1804, the cavity is filled, and in block 1806, the substrate core 202 is planarized, as shown in FIG. 20. In block 1808, a laminate layer 2102 is placed on the substrate core 202, as shown in FIG. 21.

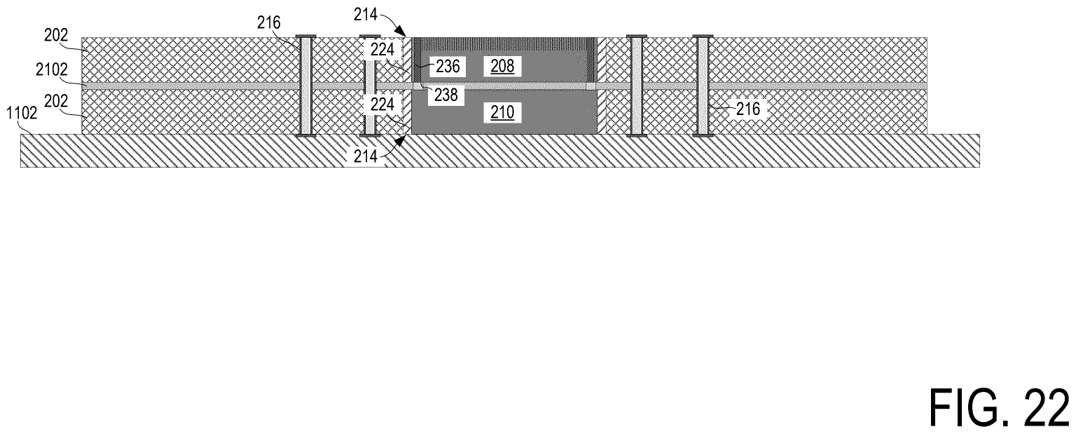

In block 1810, a second substrate core 202 with a power component 208 is placed on the first substrate core 202, as shown in FIG. 22. In another embodiment, the second substrate core 202 may be placed on the first substrate core 202 without second power component 208, and the power component 208 may be added in a similar manner as the memory component 210.

In block 1812, the substrate core 202 is removed from the carrier 1102. In block 1814, build-up layers 204, 206 are built up on the substrate core 202. In block 1816, one or more dies 104, 106 are mounted on the substrate, completing the integrated circuit component 100.

It should be appreciated that the embodiments described above are merely some possible embodiments, and other embodiments with different features or different combinations of the features disclosed herein are envisioned as well. A description of some but not all of the envisioned embodiments are described below.

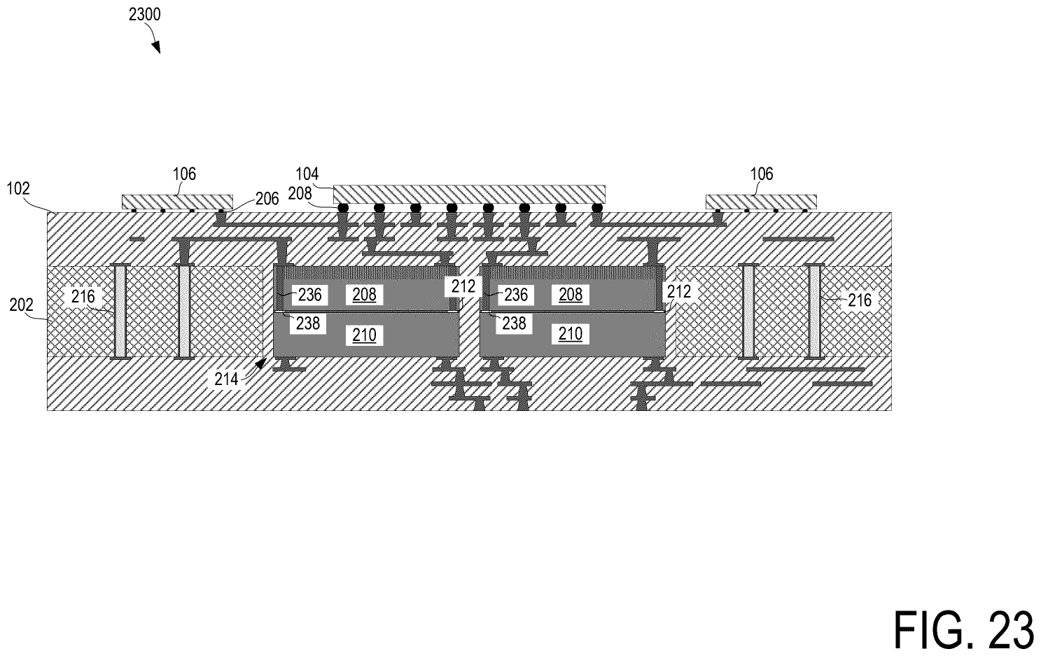

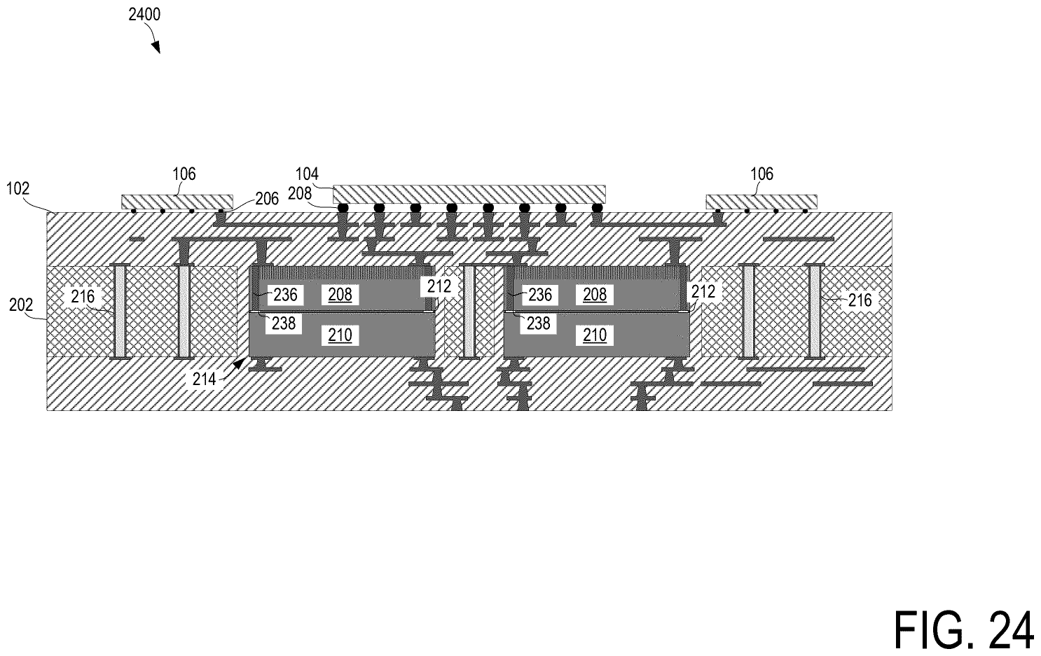

Referring now to FIG. 23, in some embodiments, an integrated circuit component 2300 may include two or more stacks of components 208, 210 in the same cavity 214. Additionally or alternatively, in some embodiments, an integrated circuit component 2400 may include two or more stacks of components 208, 210 in different cavities 214, as shown in FIG. 24.

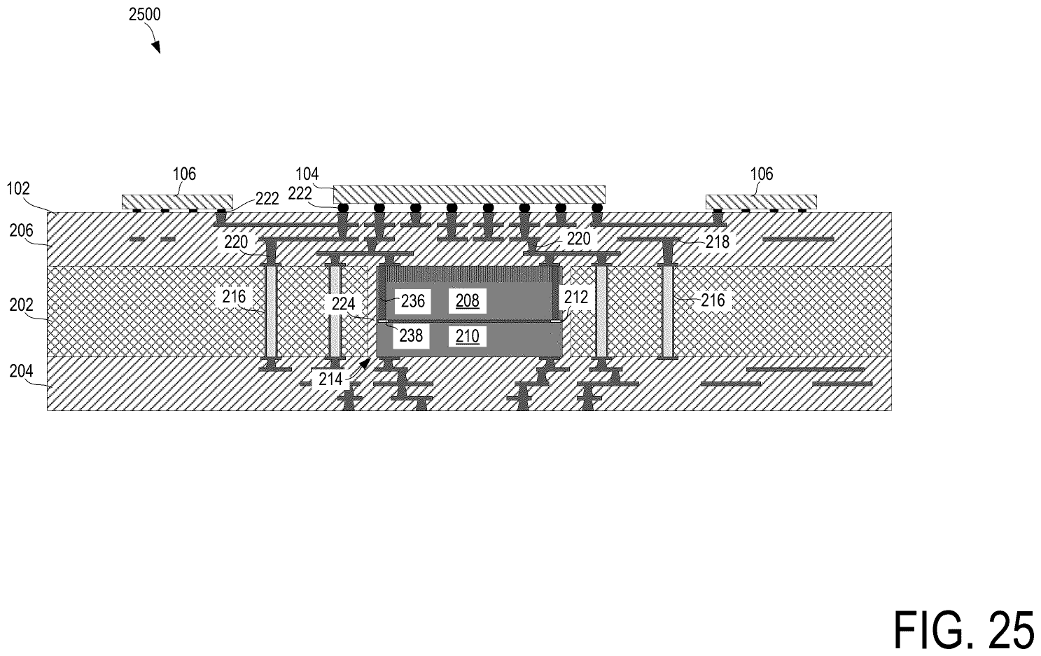

In the embodiment described above in regard to FIG. 2, the components 208, 210 have about the same height. In other embodiments, the components 208, 210 may have different heights. For example, the memory component 210 may have a smaller height than the height of the power component 208, as shown in an integrated circuit component 2500 in FIG. 25.

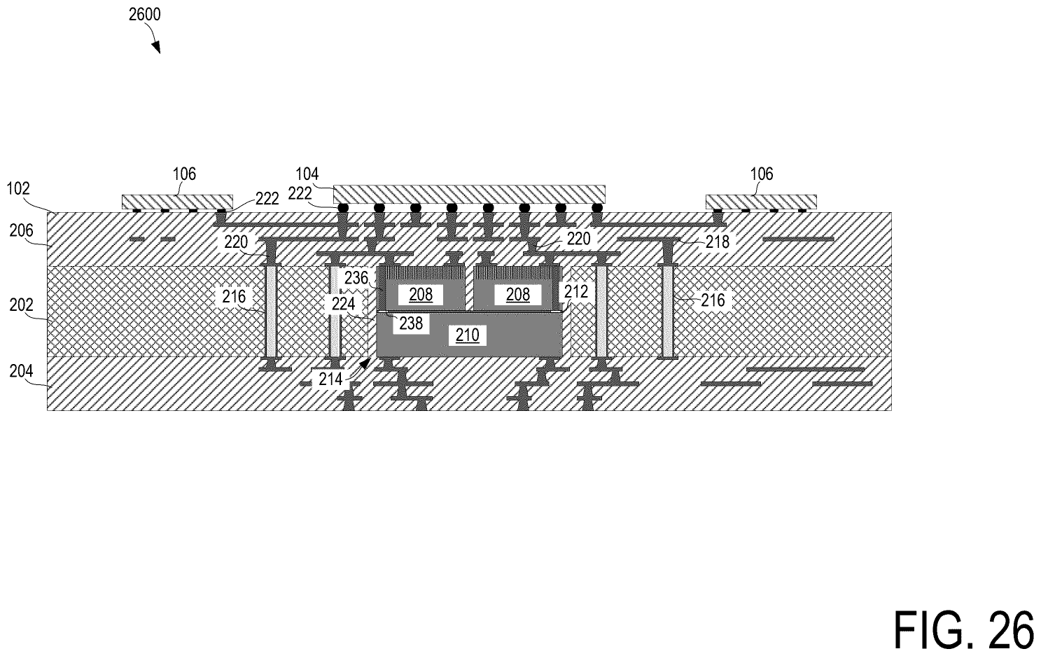

In the embodiment described above in regard to FIG. 2, the stack of components includes one memory component 210 and one power component 208. In another embodiment, several memory components 210 and/or several power components 208 may be included in one stack. For example, as shown in FIG. 26, in one embodiment, two power components 208 may be disposed on one memory component 210 of an integrated circuit component 2600.

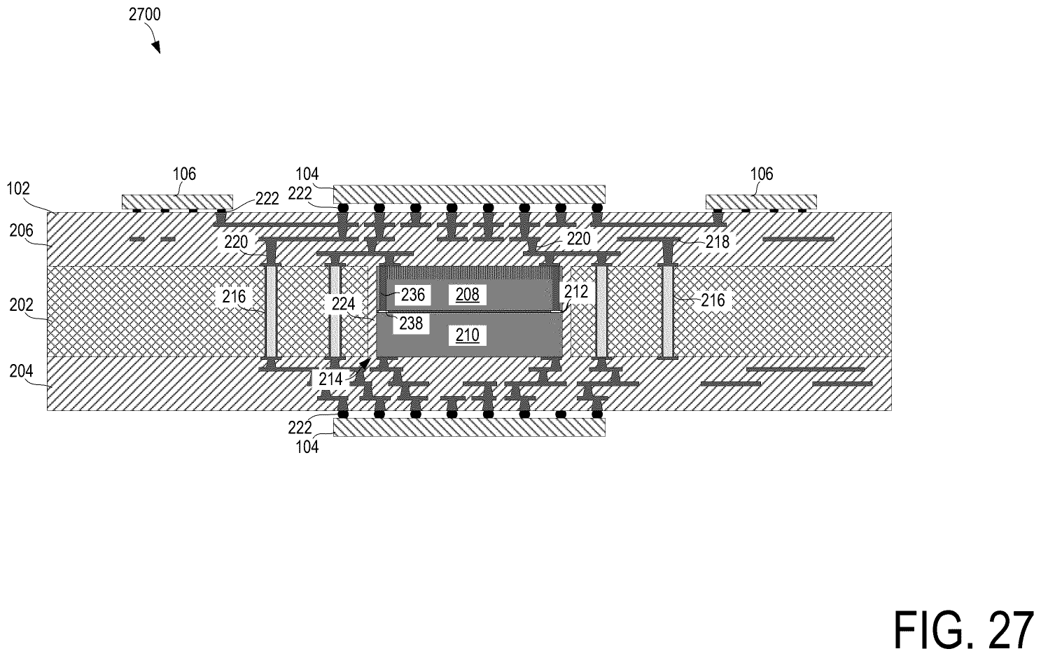

In another possible embodiment, an integrated circuit component 2700 may include a die 104 mounted on the bottom side of the circuit board 102, as shown in FIG. 27.

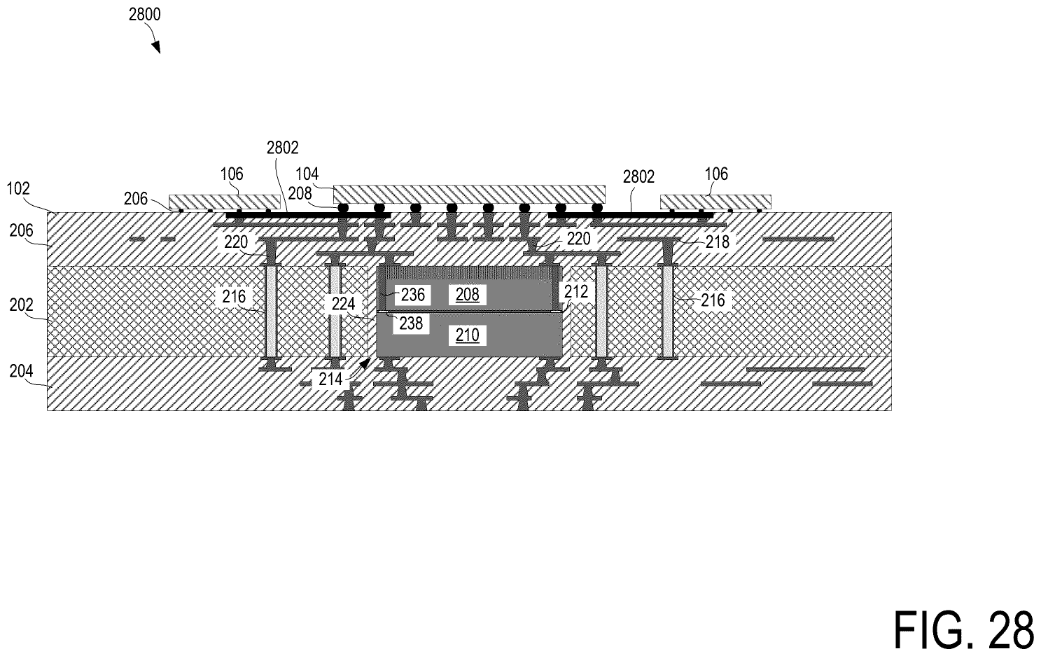

In another possible embodiment, as shown in FIG. 28 a bridge die 2802 may be disposed on or within the circuit board 102 of an integrated circuit component 2800, such as within the upper build-up layers 206. The bridge die 2802 can provide interconnects between various components, such as between the dies 104, 106 of the integrated circuit component 100 or between a die 104, 106 and a connection external to the integrated circuit component 100. The bridge die 2802 may be embodied as, e.g., an embedded multi-die interconnect bridge (EMIB) or an omni-directional interconnect (ODI). In some embodiments, die-to-die connectivity or a bridge die may be integrated into the power component 208 and/or the memory component 210.

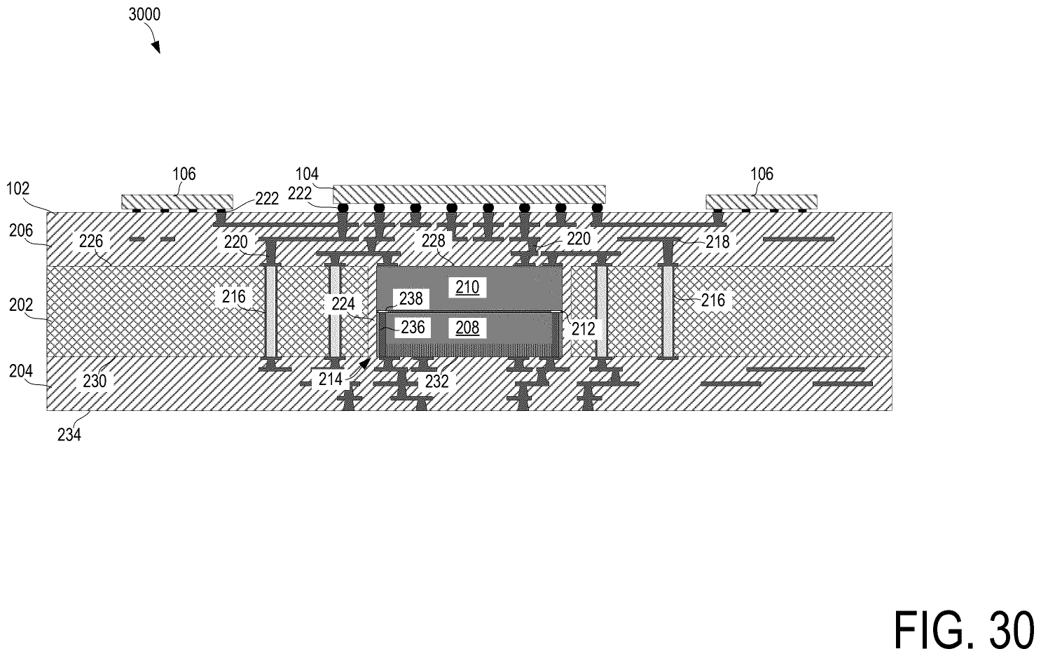

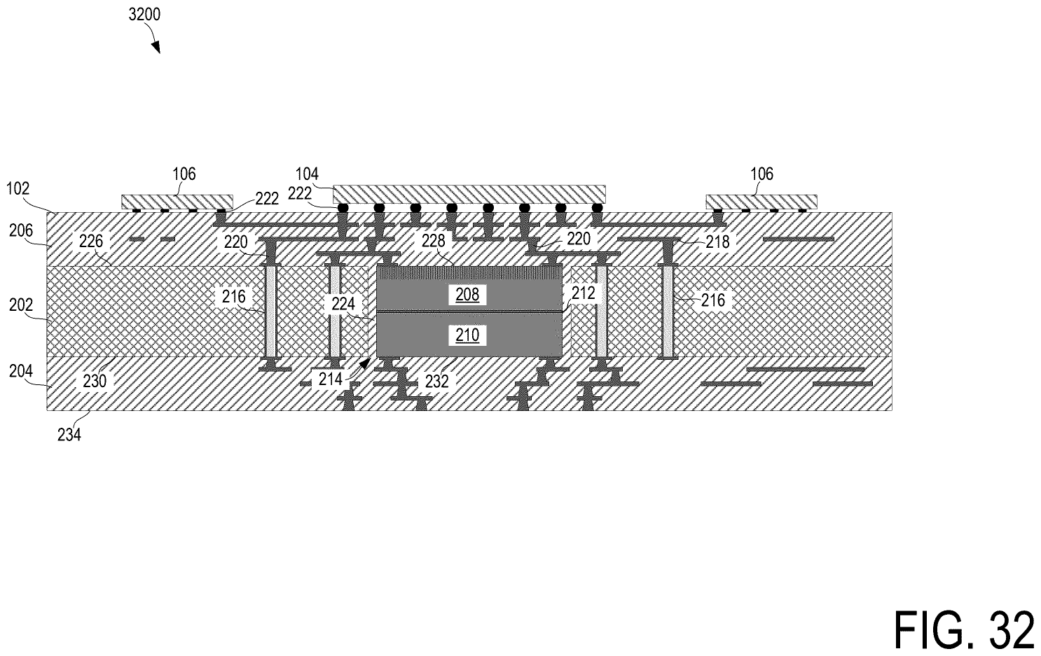

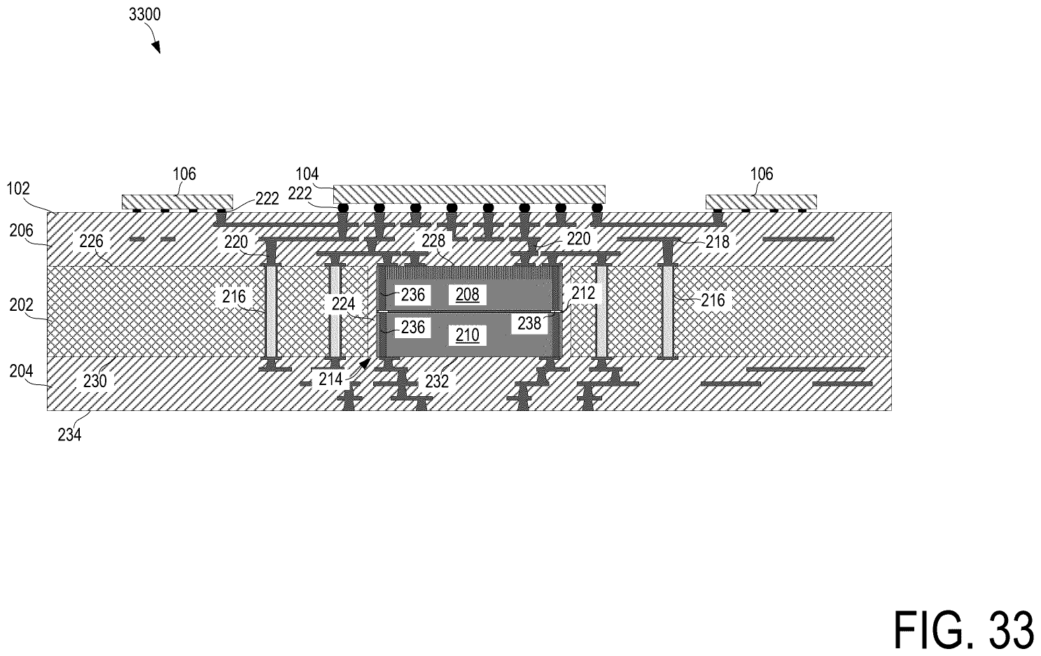

In another possible embodiment, through-silicon vias (TSVs) 236 may be present within the memory component 210 instead of the power component 208, as shown in FIG. 29. In another configuration, the power component 208 with the TSVs 236 may be above the memory component 210, as shown in FIG. 30. In another configuration, copper pillars 3102 next to the power component 208 may be used to connect to the memory component 210, as shown in FIG. 31. In another configuration, neither the memory component 210 nor the power component 208 may include TSVs 236, as shown in FIG. 32. In another configuration, both the memory component 210 and the power component 208 may include one or more TSVs 236, as shown in FIG. 33.

It should be appreciated that the integrated circuit component 100 and other integrated circuit components described herein may have additional components not shown, such as additional semiconductor dies, active component, passive components, heat management components such as integrated heat spreaders and heat sinks, etc. In some embodiments, components 208, 210 may be embedded in a circuit board 102 below a die 104 in an integrated circuit component 100, as shown in several figures above. In other embodiments, the components 208, 210 may be embedded in any suitable circuit board 102, such as a motherboard, daughterboard, riser board, power distribution board, mezzanine board, auxiliary board, and/or the like.

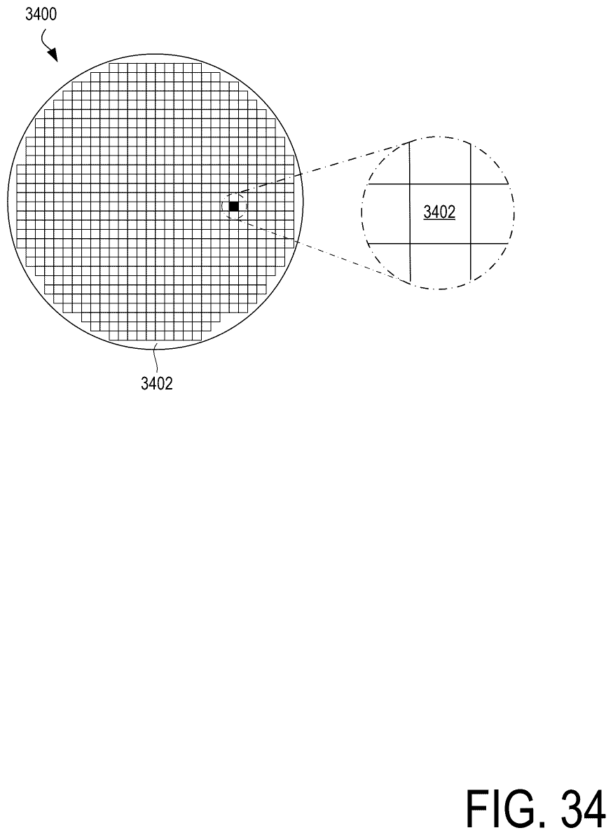

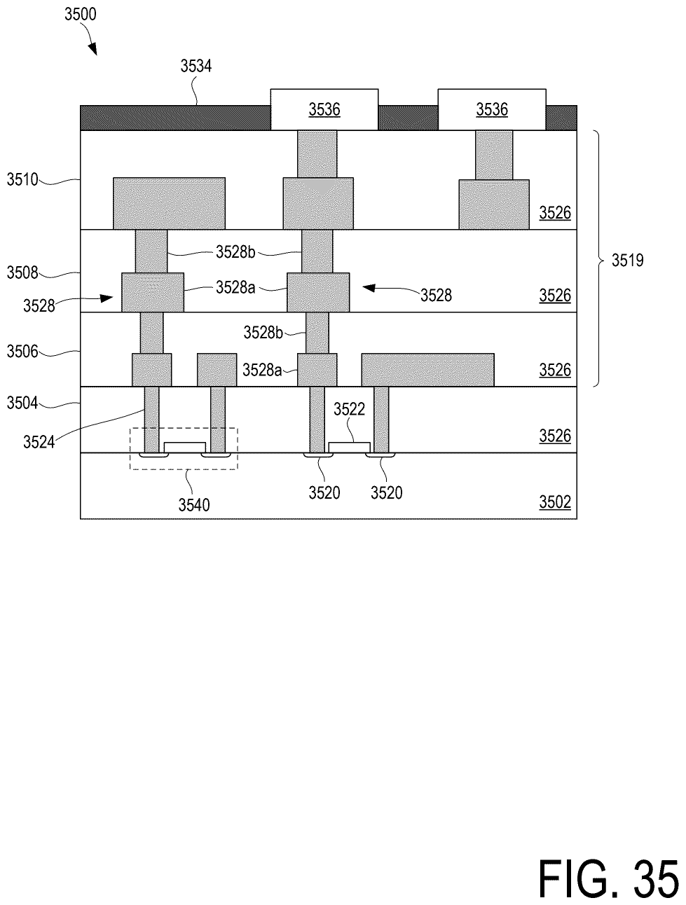

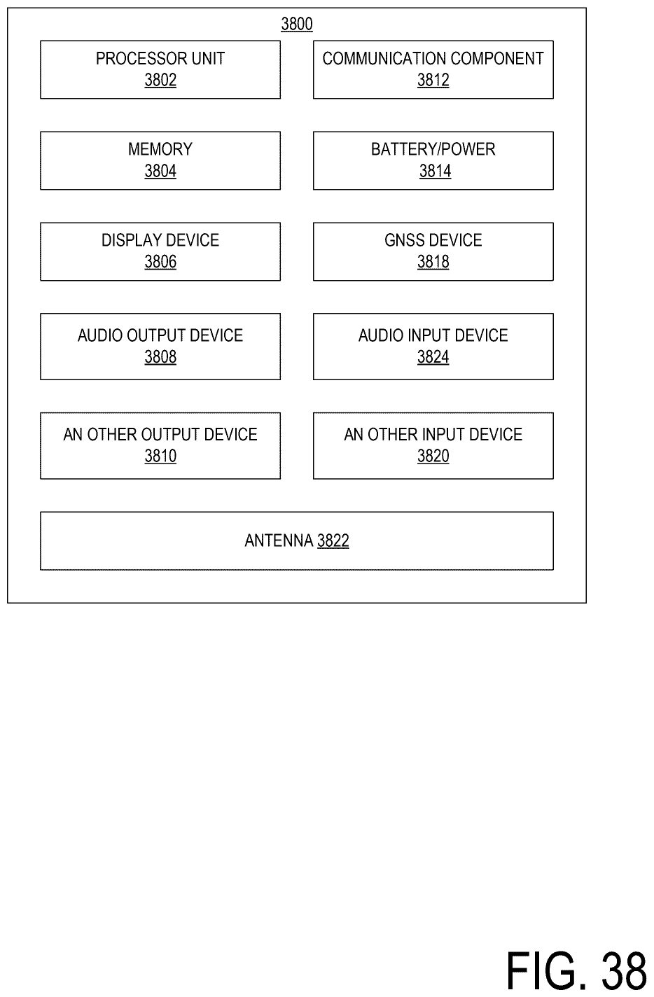

FIG. 34 is a top view of a wafer 3400 and dies 3402 that may be included in any of the integrated circuit components 100 disclosed herein (e.g., as any suitable ones of the components 208, 210 or dies 104). The wafer 3400 may be composed of semiconductor material and may include one or more dies 3402 having integrated circuit structures formed on a surface of the wafer 3400. The individual dies 3402 may be a repeating unit of an integrated circuit product that includes any suitable integrated circuit. After the fabrication of the semiconductor product is complete, the wafer 3400 may undergo a singulation process in which the dies 3402 are separated from one another to provide discrete “chips” of the integrated circuit product. The die 3402 may be any of the components 208, 210 or dies 104 disclosed herein. The die 3402 may include one or more transistors (e.g., some of the transistors 3540 of FIG. 35, discussed below), supporting circuitry to route electrical signals to the transistors, passive components (e.g., signal traces, resistors, capacitors, or inductors), and/or any other integrated circuit components. In some embodiments, the wafer 3400 or the die 3402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 3402. For example, a memory array formed by multiple memory devices may be formed on a same die 3402 as a processor unit (e.g., the processor unit 3802 of FIG. 38) or other logic that is configured to store information in the memory devices or execute instructions stored in the memory array. Various ones of the integrated circuit components 100 disclosed herein may be manufactured using a die-to-wafer assembly technique in which some components 208, 210 or dies 104 are attached to a wafer 3400 that include others of the components 208, 210 or dies 104, and the wafer 3400 is subsequently singulated.

FIG. 35 is a cross-sectional side view of an integrated circuit device 3500 that may be included in any of the integrated circuit components 100 disclosed herein (e.g., in any of the components 208, 210 or dies 104). One or more of the integrated circuit devices 3500 may be included in one or more dies 3402 (FIG. 34). The integrated circuit device 3500 may be formed on a die substrate 3502 (e.g., the wafer 3400 of FIG. 34) and may be included in a die (e.g., the die 3402 of FIG. 34). The die substrate 3502 may be a semiconductor substrate composed of semiconductor material systems including, for example, n-type or p-type materials systems (or a combination of both). The die substrate 3502 may include, for example, a crystalline substrate formed using a bulk silicon or a silicon-on-insulator (SOI) substructure. In some embodiments, the die substrate 3502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 3502. Although a few examples of materials from which the die substrate 3502 may be formed are described here, any material that may serve as a foundation for an integrated circuit device 3500 may be used. The die substrate 3502 may be part of a singulated die (e.g., the dies 3402 of FIG. 34) or a wafer (e.g., the wafer 3400 of FIG. 34).

The integrated circuit device 3500 may include one or more device layers 3504 disposed on the die substrate 3502. The device layer 3504 may include features of one or more transistors 3540 (e.g., metal oxide semiconductor field-effect transistors (MOSFETs)) formed on the die substrate 3502. The transistors 3540 may include, for example, one or more source and/or drain (S/D) regions 3520, a gate 3522 to control current flow between the S/D regions 3520, and one or more S/D contacts 3524 to route electrical signals to/from the S/D regions 3520. The transistors 3540 may include additional features not depicted for the sake of clarity, such as device isolation regions, gate contacts, and the like. The transistors 3540 are not limited to the type and configuration depicted in FIG. 35 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

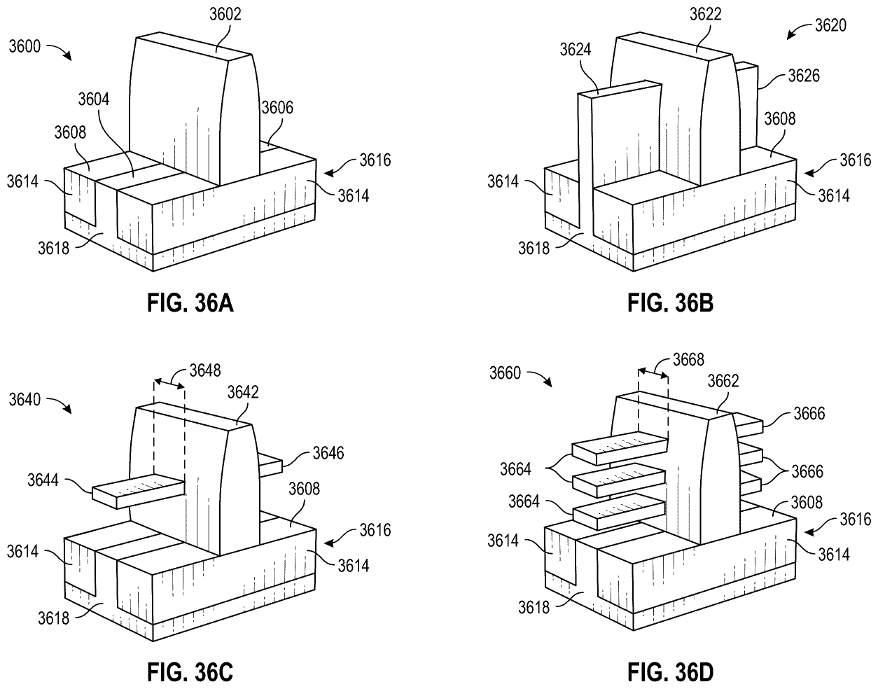

FIGS. 36A-36D are simplified perspective views of example planar, FinFET, gate-all-around, and stacked gate-all-around transistors. The transistors illustrated in FIGS. 36A-36D are formed on a substrate 3616 having a surface 3608. Isolation regions 3614 separate the source and drain regions of the transistors from other transistors and from a bulk region 3618 of the substrate 3616.

FIG. 36A is a perspective view of an example planar transistor 3600 comprising a gate 3602 that controls current flow between a source region 3604 and a drain region 3606. The transistor 3600 is planar in that the source region 3604 and the drain region 3606 are planar with respect to the substrate surface 3608.

FIG. 36B is a perspective view of an example FinFET transistor 3620 comprising a gate 3622 that controls current flow between a source region 3624 and a drain region 3626. The transistor 3620 is non-planar in that the source region 3624 and the drain region 3626 comprise “fins” that extend upwards from the substrate surface 3628. As the gate 3622 encompasses three sides of the semiconductor fin that extends from the source region 3624 to the drain region 3626, the transistor 3620 can be considered a tri-gate transistor. FIG. 36B illustrates one S/D fin extending through the gate 3622, but multiple S/D fins can extend through the gate of a FinFET transistor.

FIG. 36C is a perspective view of a gate-all-around (GAA) transistor 3640 comprising a gate 3642 that controls current flow between a source region 3644 and a drain region 3646. The transistor 3640 is non-planar in that the source region 3644 and the drain region 3646 are elevated from the substrate surface 3628.

FIG. 36D is a perspective view of a GAA transistor 3660 comprising a gate 3662 that controls current flow between multiple elevated source regions 3664 and multiple elevated drain regions 3666. The transistor 3660 is a stacked GAA transistor as the gate controls the flow of current between multiple elevated S/D regions stacked on top of each other. The transistors 3640 and 3660 are considered gate-all-around transistors as the gates encompass all sides of the semiconductor portions that extends from the source regions to the drain regions. The transistors 3640 and 3660 can alternatively be referred to as nanowire, nanosheet, or nanoribbon transistors depending on the width (e.g., widths 3648 and 3668 of transistors 3640 and 3660, respectively) of the semiconductor portions extending through the gate.

Returning to FIG. 35, a transistor 3540 may include a gate 3522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 3540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 3540 along the source-channel-drain direction, the gate electrode may consist of a U-shaped structure that includes a bottom portion substantially parallel to the surface of the die substrate 3502 and two sidewall portions that are substantially perpendicular to the top surface of the die substrate 3502. In other embodiments, at least one of the metal layers that form the gate electrode may simply be a planar layer that is substantially parallel to the top surface of the die substrate 3502 and does not include sidewall portions substantially perpendicular to the top surface of the die substrate 3502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 3520 may be formed within the die substrate 3502 adjacent to the gate 3522 of individual transistors 3540. The S/D regions 3520 may be formed using an implantation/diffusion process or an etching/deposition process, for example. In the former process, dopants such as boron, aluminum, antimony, phosphorous, or arsenic may be ion-implanted into the die substrate 3502 to form the S/D regions 3520. An annealing process that activates the dopants and causes them to diffuse farther into the die substrate 3502 may follow the ion-implantation process. In the latter process, the die substrate 3502 may first be etched to form recesses at the locations of the S/D regions 3520. An epitaxial deposition process may then be carried out to fill the recesses with material that is used to fabricate the S/D regions 3520. In some implementations, the S/D regions 3520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 3520 may be formed using one or more alternate semiconductor materials such as germanium or a group III-V material or alloy. In further embodiments, one or more layers of metal and/or metal alloys may be used to form the S/D regions 3520.

Electrical signals, such as power and/or input/output (I/O) signals, may be routed to and/or from the devices (e.g., transistors 3540) of the device layer 3504 through one or more interconnect layers disposed on the device layer 3504 (illustrated in FIG. 35 as interconnect layers 3506-3510). For example, electrically conductive features of the device layer 3504 (e.g., the gate 3522 and the S/D contacts 3524) may be electrically coupled with the interconnect structures 3528 of the interconnect layers 3506-3510. The one or more interconnect layers 3506-3510 may form a metallization stack (also referred to as an “ILD stack”) 3519 of the integrated circuit device 3500.

The interconnect structures 3528 may be arranged within the interconnect layers 3506-3510 to route electrical signals according to a wide variety of designs; in particular, the arrangement is not limited to the particular configuration of interconnect structures 3528 depicted in FIG. 35. Although a particular number of interconnect layers 3506-3510 is depicted in FIG. 35, embodiments of the present disclosure include integrated circuit devices having more or fewer interconnect layers than depicted.

In some embodiments, the interconnect structures 3528 may include lines 3528a and/or vias 3528b filled with an electrically conductive material such as a metal. The lines 3528a may be arranged to route electrical signals in a direction of a plane that is substantially parallel with a surface of the die substrate 3502 upon which the device layer 3504 is formed. For example, the lines 3528a may route electrical signals in a direction in and out of the page and/or in a direction across the page. The vias 3528b may be arranged to route electrical signals in a direction of a plane that is substantially perpendicular to the surface of the die substrate 3502 upon which the device layer 3504 is formed. In some embodiments, the vias 3528b may electrically couple lines 3528a of different interconnect layers 3506-3510 together.

The interconnect layers 3506-3510 may include a dielectric material 3526 disposed between the interconnect structures 3528, as shown in FIG. 35. In some embodiments, dielectric material 3526 disposed between the interconnect structures 3528 in different ones of the interconnect layers 3506-3510 may have different compositions; in other embodiments, the composition of the dielectric material 3526 between different interconnect layers 3506-3510 may be the same. The device layer 3504 may include a dielectric material 3526 disposed between the transistors 3540 and a bottom layer of the metallization stack as well. The dielectric material 3526 included in the device layer 3504 may have a different composition than the dielectric material 3526 included in the interconnect layers 3506-3510; in other embodiments, the composition of the dielectric material 3526 in the device layer 3504 may be the same as a dielectric material 3526 included in any one of the interconnect layers 3506-3510.

A first interconnect layer 3506 (referred to as Metal 1 or “M1”) may be formed directly on the device layer 3504. In some embodiments, the first interconnect layer 3506 may include lines 3528a and/or vias 3528b, as shown. The lines 3528a of the first interconnect layer 3506 may be coupled with contacts (e.g., the S/D contacts 3524) of the device layer 3504. The vias 3528b of the first interconnect layer 3506 may be coupled with the lines 3528a of a second interconnect layer 3508.

The second interconnect layer 3508 (referred to as Metal 2 or “M2”) may be formed directly on the first interconnect layer 3506. In some embodiments, the second interconnect layer 3508 may include via 3528b to couple the lines 3528 of the second interconnect layer 3508 with the lines 3528a of a third interconnect layer 3510. Although the lines 3528a and the vias 3528b are structurally delineated with a line within individual interconnect layers for the sake of clarity, the lines 3528a and the vias 3528b may be structurally and/or materially contiguous (e.g., simultaneously filled during a dual-damascene process) in some embodiments.

The third interconnect layer 3510 (referred to as Metal 3 or “M3”) (and additional interconnect layers, as desired) may be formed in succession on the second interconnect layer 3508 according to similar techniques and configurations described in connection with the second interconnect layer 3508 or the first interconnect layer 3506. In some embodiments, the interconnect layers that are “higher up” in the metallization stack 3519 in the integrated circuit device 3500 (i.e., farther away from the device layer 3504) may be thicker that the interconnect layers that are lower in the metallization stack 3519, with lines 3528a and vias 3528b in the higher interconnect layers being thicker than those in the lower interconnect layers.

The integrated circuit device 3500 may include a solder resist material 3534 (e.g., polyimide or similar material) and one or more conductive contacts 3536 formed on the interconnect layers 3506-3510. In FIG. 35, the conductive contacts 3536 are illustrated as taking the form of bond pads. The conductive contacts 3536 may be electrically coupled with the interconnect structures 3528 and configured to route the electrical signals of the transistor(s) 3540 to external devices. For example, solder bonds may be formed on the one or more conductive contacts 3536 to mechanically and/or electrically couple an integrated circuit die including the integrated circuit device 3500 with another component (e.g., a printed circuit board). The integrated circuit device 3500 may include additional or alternate structures to route the electrical signals from the interconnect layers 3506-3510; for example, the conductive contacts 3536 may include other analogous features (e.g., posts) that route the electrical signals to external components.

In some embodiments in which the integrated circuit device 3500 is a double-sided die, the integrated circuit device 3500 may include another metallization stack (not shown) on the opposite side of the device layer(s) 3504. This metallization stack may include multiple interconnect layers as discussed above with reference to the interconnect layers 3506-3510, to provide conductive pathways (e.g., including conductive lines and vias) between the device layer(s) 3504 and additional conductive contacts (not shown) on the opposite side of the integrated circuit device 3500 from the conductive contacts 3536.

In other embodiments in which the integrated circuit device 3500 is a double-sided die, the integrated circuit device 3500 may include one or more through silicon vias (TSVs) through the die substrate 3502; these TSVs may make contact with the device layer(s) 3504, and may provide conductive pathways between the device layer(s) 3504 and additional conductive contacts (not shown) on the opposite side of the integrated circuit device 3500 from the conductive contacts 3536. In some embodiments, TSVs extending through the substrate can be used for routing power and ground signals from conductive contacts on the opposite side of the integrated circuit device 3500 from the conductive contacts 3536 to the transistors 3540 and any other components integrated into the die 3500, and the metallization stack 3519 can be used to route I/O signals from the conductive contacts 3536 to transistors 3540 and any other components integrated into the die 3500.

Multiple integrated circuit devices 3500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

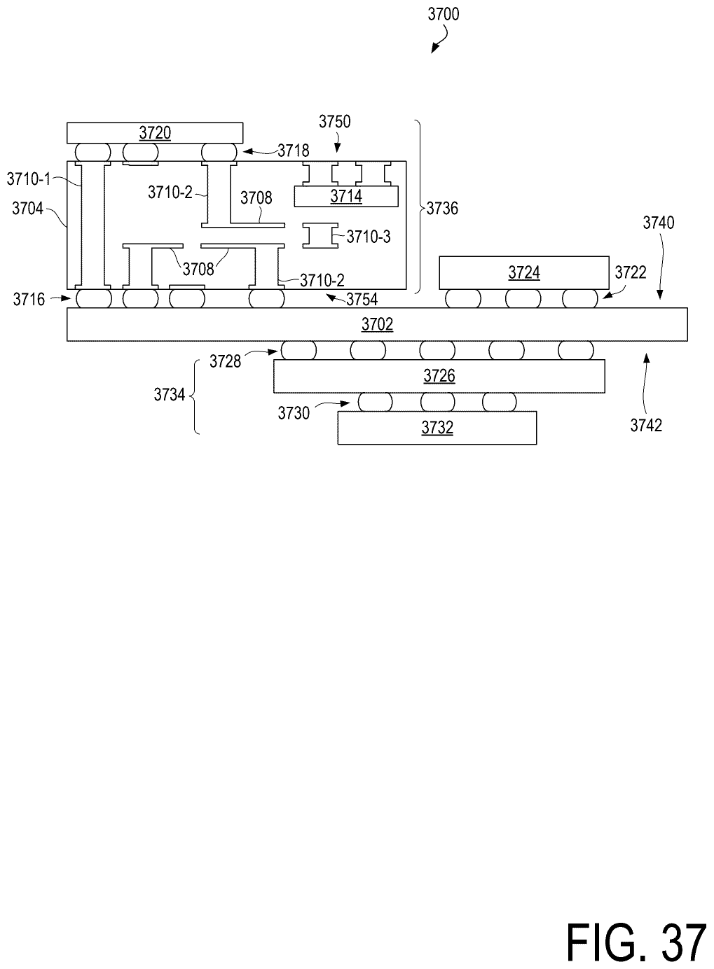

FIG. 37 is a cross-sectional side view of an integrated circuit device assembly 3700 that may include any of the integrated circuit components 100, 2300, 2400, 2500, 2600, 2700, 2800, 2900, 3000, 3100, 3200, 3300 disclosed herein. In some embodiments, the integrated circuit device assembly 3700 may be a integrated circuit components 100, 2300, 2400, 2500, 2600, 2700, 2800, 2900, 3000, 3100, 3200, 3300. The integrated circuit device assembly 3700 includes a number of components disposed on a circuit board 3702 (which may be a motherboard, system board, mainboard, etc.). The integrated circuit device assembly 3700 includes components disposed on a first face 3740 of the circuit board 3702 and an opposing second face 3742 of the circuit board 3702; generally, components may be disposed on one or both faces 3740 and 3742. Any of the integrated circuit components discussed below with reference to the integrated circuit device assembly 3700 may take the form of any suitable ones of the embodiments of the integrated circuit components 100, 2300, 2400, 2500, 2600, 2700, 2800, 2900, 3000, 3100, 3200, 3300 disclosed herein.

In some embodiments, the circuit board 3702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 3702. In other embodiments, the circuit board 3702 may be a non-PCB substrate. In some embodiments the circuit board 3702 may be, for example, the circuit board 102. The integrated circuit device assembly 3700 illustrated in FIG. 37 includes a package-on-interposer structure 3736 coupled to the first face 3740 of the circuit board 3702 by coupling components 3716. The coupling components 3716 may electrically and mechanically couple the package-on-interposer structure 3736 to the circuit board 3702, and may include solder balls (as shown in FIG. 37), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 3736 may include an integrated circuit component 3720 coupled to an interposer 3704 by coupling components 3718. The coupling components 3718 may take any suitable form for the application, such as the forms discussed above with reference to the coupling components 3716. Although a single integrated circuit component 3720 is shown in FIG. 37, multiple integrated circuit components may be coupled to the interposer 3704; indeed, additional interposers may be coupled to the interposer 3704. The interposer 3704 may provide an intervening substrate used to bridge the circuit board 3702 and the integrated circuit component 3720.

The integrated circuit component 3720 may be a packaged or unpacked integrated circuit product that includes one or more integrated circuit dies (e.g., the die 3402 of FIG. 34, the integrated circuit device 3500 of FIG. 35) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 3720, a single monolithic integrated circuit die comprises solder bumps attached to contacts on the die. The solder bumps allow the die to be directly attached to the interposer 3704. The integrated circuit component 3720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 3720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 3720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 3720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 3704 may spread connections to a wider pitch or reroute a connection to a different connection. For example, the interposer 3704 may couple the integrated circuit component 3720 to a set of ball grid array (BGA) conductive contacts of the coupling components 3716 for coupling to the circuit board 3702. In the embodiment illustrated in FIG. 37, the integrated circuit component 3720 and the circuit board 3702 are attached to opposing sides of the interposer 3704; in other embodiments, the integrated circuit component 3720 and the circuit board 3702 may be attached to a same side of the interposer 3704. In some embodiments, three or more components may be interconnected by way of the interposer 3704.

In some embodiments, the interposer 3704 may be formed as a PCB, including multiple metal layers separated from one another by layers of dielectric material and interconnected by electrically conductive vias. In some embodiments, the interposer 3704 may be formed of an epoxy resin, a fiberglass-reinforced epoxy resin, an epoxy resin with inorganic fillers, a ceramic material, or a polymer material such as polyimide. In some embodiments, the interposer 3704 may be formed of alternate rigid or flexible materials that may include the same materials described above for use in a semiconductor substrate, such as silicon, germanium, and other group III-V and group IV materials. The interposer 3704 may include metal interconnects 3708 and vias 3710, including but not limited to through hole vias 3710-1 (that extend from a first face 3750 of the interposer 3704 to a second face 3754 of the interposer 3704), blind vias 3710-2 (that extend from the first or second faces 3750 or 3754 of the interposer 3704 to an internal metal layer), and buried vias 3710-3 (that connect internal metal layers).

In some embodiments, the interposer 3704 can comprise a silicon interposer. Through silicon vias (TSV) extending through the silicon interposer can connect connections on a first face of a silicon interposer to an opposing second face of the silicon interposer. In some embodiments, an interposer 3704 comprising a silicon interposer can further comprise one or more routing layers to route connections on a first face of the interposer 3704 to an opposing second face of the interposer 3704.

The interposer 3704 may further include embedded devices 3714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3704. The package-on-interposer structure 3736 may take the form of any of the package-on-interposer structures known in the art.

The integrated circuit device assembly 3700 may include an integrated circuit component 3724 coupled to the first face 3740 of the circuit board 3702 by coupling components 3722. The coupling components 3722 may take the form of any of the embodiments discussed above with reference to the coupling components 3716, and the integrated circuit component 3724 may take the form of any of the embodiments discussed above with reference to the integrated circuit component 3720.

The integrated circuit device assembly 3700 illustrated in FIG. 37 includes a package-on-package structure 3734 coupled to the second face 3742 of the circuit board 3702 by coupling components 3728. The package-on-package structure 3734 may include an integrated circuit component 3726 and an integrated circuit component 3732 coupled together by coupling components 3730 such that the integrated circuit component 3726 is disposed between the circuit board 3702 and the integrated circuit component 3732. The coupling components 3728 and 3730 may take the form of any of the embodiments of the coupling components 3716 discussed above, and the integrated circuit components 3726 and 3732 may take the form of any of the embodiments of the integrated circuit component 3720 discussed above. The package-on-package structure 3734 may be configured in accordance with any of the package-on-package structures known in the art.

FIG. 38 is a block diagram of an example electrical device 3800 that may include one or more of the integrated circuit components 100, 2300, 2400, 2500, 2600, 2700, 2800, 2900, 3000, 3100, 3200, 3300 disclosed herein. For example, any suitable ones of the components of the electrical device 3800 may include one or more of the integrated circuit device assemblies 3700, integrated circuit components 3720, integrated circuit devices 3500, or integrated circuit dies 3402 disclosed herein, and may be arranged in any of the integrated circuit components 100, 2300, 2400, 2500, 2600, 2700, 2800, 2900, 3000, 3100, 3200, 3300 disclosed herein. A number of components are illustrated in FIG. 38 as included in the electrical device 3800, but any one or more of these components may be omitted or duplicated, as suitable for the application. In some embodiments, some or all of the components included in the electrical device 3800 may be attached to one or more motherboards mainboards, or system boards. In some embodiments, one or more of these components are fabricated onto a single system-on-a-chip (SoC) die.

Additionally, in various embodiments, the electrical device 3800 may not include one or more of the components illustrated in FIG. 38, but the electrical device 3800 may include interface circuitry for coupling to the one or more components. For example, the electrical device 3800 may not include a display device 3806, but may include display device interface circuitry (e.g., a connector and driver circuitry) to which a display device 3806 may be coupled. In another set of examples, the electrical device 3800 may not include an audio input device 3824 or an audio output device 3808, but may include audio input or output device interface circuitry (e.g., connectors and supporting circuitry) to which an audio input device 3824 or audio output device 3808 may be coupled.

The electrical device 3800 may include one or more processor units 3802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 3802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3800 may include a memory 3804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3804 may include memory that is located on the same integrated circuit die as the processor unit 3802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 3800 can comprise one or more processor units 3802 that are heterogeneous or asymmetric to another processor unit 3802 in the electrical device 3800. There can be a variety of differences between the processing units 3802 in a system in terms of a spectrum of metrics of merit including architectural, microarchitectural, thermal, power consumption characteristics, and the like. These differences can effectively manifest themselves as asymmetry and heterogeneity among the processor units 3802 in the electrical device 3800.

In some embodiments, the electrical device 3800 may include a communication component 3812 (e.g., one or more communication components). For example, the communication component 3812 can manage wireless communications for the transfer of data to and from the electrical device 3800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3812 may operate in accordance with Enhanced Data for GSM

Evolution (EDGE), GSM EDGE Radio Access Network (GERAN), Universal Terrestrial Radio Access Network (UTRAN), or Evolved UTRAN (E-UTRAN). The communication component 3812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3812 may operate in accordance with other wireless protocols in other embodiments. The electrical device 3800 may include an antenna 3822 to facilitate wireless communications and/or to receive other wireless communications (such as AM or FM radio transmissions).

In some embodiments, the communication component 3812 may manage wired communications, such as electrical, optical, or any other suitable communication protocols (e.g., IEEE 802.3 Ethernet standards). As noted above, the communication component 3812 may include multiple communication components. For instance, a first communication component 3812 may be dedicated to shorter-range wireless communications such as Wi-Fi or Bluetooth, and a second communication component 3812 may be dedicated to longer-range wireless communications such as global positioning system (GPS), EDGE, GPRS, CDMA, WiMAX, LTE, EV-DO, or others. In some embodiments, a first communication component 3812 may be dedicated to wireless communications, and a second communication component 3812 may be dedicated to wired communications.

The electrical device 3800 may include battery/power circuitry 3814. The battery/power circuitry 3814 may include one or more energy storage devices (e.g., batteries or capacitors) and/or circuitry for coupling components of the electrical device 3800 to an energy source separate from the electrical device 3800 (e.g., AC line power).

The electrical device 3800 may include a display device 3806 (or corresponding interface circuitry, as discussed above). The display device 3806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3800 may include an audio output device 3808 (or corresponding interface circuitry, as discussed above). The audio output device 3808 may include any embedded or wired or wirelessly connected external device that generates an audible indicator, such as speakers, headsets, or earbuds.

The electrical device 3800 may include an audio input device 3824 (or corresponding interface circuitry, as discussed above). The audio input device 3824 may include any embedded or wired or wirelessly connected device that generates a signal representative of a sound, such as microphones, microphone arrays, or digital instruments (e.g., instruments having a musical instrument digital interface (MIDI) output). The electrical device 3800 may include a Global Navigation Satellite System (GNSS) device 3818 (or corresponding interface circuitry, as discussed above), such as a Global Positioning System (GPS) device. The GNSS device 3818 may be in communication with a satellite-based system and may determine a geolocation of the electrical device 3800 based on information received from one or more GNSS satellites, as known in the art.

The electrical device 3800 may include an other output device 3810 (or corresponding interface circuitry, as discussed above). Examples of the other output device 3810 may include an audio codec, a video codec, a printer, a wired or wireless transmitter for providing information to other devices, or an additional storage device.

The electrical device 3800 may include an other input device 3820 (or corresponding interface circuitry, as discussed above). Examples of the other input device 3820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3800 may be any other electronic device that processes data. In some embodiments, the electrical device 3800 may comprise multiple discrete physical components. Given the range of devices that the electrical device 3800 can be manifested as in various embodiments, in some embodiments, the electrical device 3800 can be referred to as a computing device or a computing system.

### Examples

Illustrative examples of the technologies disclosed herein are provided below. An embodiment of the technologies may include any one or more, and any combination of, the examples described below.

Example 1 includes an apparatus comprising a substrate core, wherein a cavity is defined in the substrate core; a first die disposed in the cavity, the first die comprising a capacitor; and a second die disposed in the cavity, wherein the second die is a memory die, wherein the second die is disposed above or below the first die.

Example 2 includes the subject matter of Example 1, and wherein the first die is a deep trench capacitor die.

Example 3 includes the subject matter of any of Examples 1 and 2, and wherein the first die comprises a plurality of trenches, wherein individual trenches of the plurality of trenches extend from a surface of the first die to at least 10 micrometers below the surface of the first die.

Example 4 includes the subject matter of any of Examples 1-3, and wherein the second die is part of a high-bandwidth memory stack comprising a plurality of dies.

Example 5 includes the subject matter of any of Examples 1-4, and wherein the second die is a dynamic random-access memory (DRAM) die.

Example 6 includes the subject matter of any of Examples 1-5, and wherein the second die is a static random-access memory (SRAM) die.

Example 7 includes the subject matter of any of Examples 1-6, and wherein the second die is a NAND memory die.

Example 8 includes the subject matter of any of Examples 1-7, and wherein the first die comprises a magnetic inductor array.

Example 9 includes the subject matter of any of Examples 1-8, and wherein the second die or the first die or both comprise die-to-die connectivity circuitry.

Example 10 includes the subject matter of any of Examples 1-9, and further including one or more copper pillars next to the first die, the one or more copper pillars extending from the second die to a plane defined by a surface of the substrate core.

Example 11 includes the subject matter of any of Examples 1-10, and wherein a bottom surface of the first die is within 100 micrometers of a plane defined by a bottom surface of the substrate core, wherein a top surface of the second die is within 100 micrometers of a plane defined by a top surface of the substrate core.

Example 12 includes the subject matter of any of Examples 1-11, and wherein the substrate core has a thickness of at least 800 micrometers.

Example 13 includes the subject matter of any of Examples 1-12, and wherein a difference between a thickness of the first die and a thickness of the second die is less than five micrometers.

Example 14 includes the subject matter of any of Examples 1-13, and wherein a difference between a thickness of the first die and a thickness of the second die is at least 20 micrometers.

Example 15 includes the subject matter of any of Examples 1-14, and wherein the substrate core has a thickness less than 200 micrometers.

Example 16 includes the subject matter of any of Examples 1-15, and wherein the first die comprises one or more through-silicon vias, wherein individual through-silicon vias of the one or more through-silicon vias extend from a top surface of the first die to a bottom surface of the first die, wherein individual through-silicon vias of the one or more through-silicon vias are connected to the second die.

Example 17 includes the subject matter of any of Examples 1-16, and wherein the second die comprises one or more through-silicon vias, wherein individual through-silicon vias of the one or more through-silicon vias extend from a top surface of the second die to a bottom surface of the second die, wherein individual through-silicon vias of the one or more through-silicon vias are connected to the first die.

Example 18 includes the subject matter of any of Examples 1-17, and further including a third die disposed on a surface of a circuit board of the apparatus, wherein the third die is positioned at least partially above the first die and the second die.

Example 19 includes the subject matter of any of Examples 1-18, and further including a fourth die disposed on a second surface of the circuit board, the second surface opposite the surface, wherein the fourth die is positioned at least partially below the first die and the second die.

Example 20 includes the subject matter of any of Examples 1-19, and further including a fully-integrated voltage regulator (FIVR), wherein the FIVR comprises the first die.

Example 21 includes the subject matter of any of Examples 1-20, and further including a third die, wherein the third die comprises a capacitor, wherein the third die is disposed above the second die and next to the first die.

Example 22 includes the subject matter of any of Examples 1-21, and further including a third die, wherein the third die is a memory die, wherein the third die is disposed above the first die and next to the second die.

Example 23 includes the subject matter of any of Examples 1-22, and further including a third die disposed in the cavity, wherein the third die comprises a capacitor; and a fourth die component disposed in the cavity, wherein the fourth die is a memory die, wherein the fourth die is disposed above or below the third die.

Example 24 includes the subject matter of any of Examples 1-23, and wherein a second cavity is defined in the substrate core, the second cavity separate from the cavity, further comprising a third die disposed in the second cavity, the third die comprising a capacitor; and a fourth die disposed in the second cavity, the fourth die comprising a memory die, wherein the fourth die is disposed above the third die.

Example 25 includes the subject matter of any of Examples 1-24, and further including a plurality of build-up layers adjacent the substrate core.

Example 26 includes an apparatus comprising a substrate core comprising a top surface and a bottom surface, wherein a cavity is defined in the substrate core, wherein the cavity extends from the top surface of the substrate core to the bottom surface of the substrate core; and a power component stack disposed in the cavity, wherein the power component stack extends at least from a top plane defined by the top surface of the substrate core to a bottom plane defined by the bottom surface of the substrate core, wherein the power component stack comprises a power component and a memory component.

Example 27 includes the subject matter of Example 26, and wherein the power component is a deep trench capacitor.

Example 28 includes the subject matter of any of Examples 26 and 27, and wherein the power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 29 includes the subject matter of any of Examples 26-28, and wherein the memory component is a high-bandwidth memory stack comprising a plurality of dies.

Example 30 includes the subject matter of any of Examples 26-29, and wherein the memory component is a dynamic random-access memory (DRAM) die.

Example 31 includes the subject matter of any of Examples 26-30, and wherein the memory component is a static random-access memory (SRAM) die.

Example 32 includes the subject matter of any of Examples 26-31, and wherein the memory component is a NAND memory die.

Example 33 includes the subject matter of any of Examples 26-32, and wherein the power component is a magnetic inductor array.

Example 34 includes the subject matter of any of Examples 26-33, and wherein the memory component or the power component or both comprise die-to-die connectivity circuitry.

Example 35 includes the subject matter of any of Examples 26-34, and further including one or more copper pillars next to the power component, the one or more copper pillars extending from the memory component to a plane defined by a surface of the substrate core.

Example 36 includes the subject matter of any of Examples 26-35, and wherein a bottom surface of the power component is within 100 micrometers of a plane defined by a bottom surface of the substrate core, wherein a top surface of the memory component is within 100 micrometers of a plane defined by the top surface of the substrate core.

Example 37 includes the subject matter of any of Examples 26-36, and wherein the substrate core has a thickness of at least 800 micrometers.

Example 38 includes the subject matter of any of Examples 26-37, and wherein a difference between a thickness of the power component and a thickness of the memory component is less than five micrometers.

Example 39 includes the subject matter of any of Examples 26-38, and wherein a difference between a thickness of the power component and a thickness of the memory component is at least 20 micrometers.

Example 40 includes the subject matter of any of Examples 26-39, and wherein the substrate core has a thickness less than 200 micrometers.

Example 41 includes the subject matter of any of Examples 26-40, and wherein the power component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the memory component.

Example 42 includes the subject matter of any of Examples 26-41, and wherein the memory component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the power component.

Example 43 includes the subject matter of any of Examples 26-42, and further including a semiconductor die disposed on a surface of a circuit board of the apparatus, wherein the semiconductor die is positioned at least partially above the power component and the memory component.

Example 44 includes the subject matter of any of Examples 26-43, and further including a second semiconductor die disposed on a second surface of the circuit board, the second surface opposite the surface, wherein the second semiconductor die is positioned at least partially below the power component and the memory component.

Example 45 includes the subject matter of any of Examples 26-44, and further including a fully-integrated voltage regulator (FIVR), wherein the FIVR comprises the power component.

Example 46 includes the subject matter of any of Examples 26-45, and further including a second power component, wherein the second power component is disposed above the memory component and next to the power component.

Example 47 includes the subject matter of any of Examples 26-46, and further including a second memory component, wherein the second memory component is disposed above the power component and next to the memory component.

Example 48 includes the subject matter of any of Examples 26-47, and further including a second power component disposed in the cavity; and a second memory component disposed in the cavity, wherein the second power component is disposed above or below the second power component.

Example 49 includes the subject matter of any of Examples 26-48, and wherein a second cavity is defined in the substrate core, the second cavity separate from the cavity, further comprising a third power component disposed in the second cavity; and a fourth power component disposed in the second cavity, wherein the fourth power component is disposed above the third power component.

Example 50 includes the subject matter of any of Examples 26-49, and further including a plurality of build-up layers adjacent the substrate core.

Example 51 includes an apparatus comprising a circuit board; a semiconductor die; and a component stack disposed in the circuit board, wherein the component stack comprises a power component and a memory component.

Example 52 includes the subject matter of Example 51, and wherein the power component is a deep trench capacitor.

Example 53 includes the subject matter of any of Examples 51 and 52, and wherein the power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 54 includes the subject matter of any of Examples 51-53, and wherein the memory component is a high-bandwidth memory stack comprising a plurality of dies.

Example 55 includes the subject matter of any of Examples 51-54, and wherein the memory component is a dynamic random-access memory (DRAM) die.

Example 56 includes the subject matter of any of Examples 51-55, and wherein the memory component is a static random-access memory (SRAM) die.

Example 57 includes the subject matter of any of Examples 51-56, and wherein the memory component is a NAND memory die.

Example 58 includes the subject matter of any of Examples 51-57, and wherein the power component is a magnetic inductor array.

Example 59 includes the subject matter of any of Examples 51-58, and wherein the memory component or the power component or both comprise die-to-die connectivity circuitry.

Example 60 includes the subject matter of any of Examples 51-59, and further including one or more copper pillars next to the power component, the one or more copper pillars extending from the memory component to a plane defined by a surface of a substrate core of the circuit board.

Example 61 includes the subject matter of any of Examples 51-60, and wherein a bottom surface of the power component is within 100 micrometers of a plane defined by a bottom surface of a substrate core of the circuit board, wherein a top surface of the memory component is within 100 micrometers of a plane defined by a top surface of the substrate core.

Example 62 includes the subject matter of any of Examples 51-61, and wherein a substrate core of the circuit board has a thickness of at least 800 micrometers.

Example 63 includes the subject matter of any of Examples 51-62, and wherein a difference between a thickness of the power component and a thickness of the memory component is less than five micrometers.

Example 64 includes the subject matter of any of Examples 51-63, and wherein a difference between a thickness of the power component and a thickness of the memory component is at least 20 micrometers.

Example 65 includes the subject matter of any of Examples 51-64, and wherein a substrate core of the circuit board has a thickness less than 200 micrometers.

Example 66 includes the subject matter of any of Examples 51-65, and wherein the power component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the memory component.

Example 67 includes the subject matter of any of Examples 51-66, and wherein the memory component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the power component.

Example 68 includes the subject matter of any of Examples 51-67, and wherein the semiconductor die is positioned at least partially above the power component and the memory component.

Example 69 includes the subject matter of any of Examples 51-68, and further including a second semiconductor die disposed on the circuit board, wherein the second semiconductor die is positioned at least partially below the power component and the memory component.

Example 70 includes the subject matter of any of Examples 51-69, and further including a fully-integrated voltage regulator (FIVR), wherein the FIVR comprises the power component.

Example 71 includes the subject matter of any of Examples 51-70, and further including a second power component, wherein the second power component is disposed above the memory component and next to the power component.

Example 72 includes the subject matter of any of Examples 51-71, and further including a second memory component, wherein the second memory component is disposed above the power component and next to the memory component.

Example 73 includes the subject matter of any of Examples 51-72, and wherein a cavity is defined in a substrate core of the circuit board, wherein the power component and the memory component are disposed in the cavity, further comprising a second power component disposed in the cavity; and a second memory component disposed in the cavity, wherein the second power component is disposed above or below the second memory component.

Example 74 includes the subject matter of any of Examples 51-73, and wherein a cavity is defined in a substrate core of the circuit board, wherein the power component and the memory component are disposed in the cavity, wherein a second cavity is defined in a substrate core of the circuit board, the second cavity separate from the cavity, further comprising a second power component disposed in the second cavity; and a second memory component disposed in the second cavity, wherein the second memory component is disposed above or below the second power component.

Example 75 includes the subject matter of any of Examples 51-74, and wherein the circuit board comprises a substrate core and a plurality of build-up layers adjacent the substrate core.

Example 76 includes an apparatus comprising a substrate core, wherein a cavity is defined in the substrate core; means for providing power, wherein the means for providing power is disposed within the substrate core; and means for providing memory, wherein the means for providing memory is disposed within the substrate core.

Example 77 includes the subject matter of Example 76, and wherein the means for providing power comprises one or more deep trench capacitors.

Example 78 includes the subject matter of any of Examples 76 and 77, and wherein the means for providing power comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 79 includes the subject matter of any of Examples 76-78, and wherein the means for providing memory is a high-bandwidth memory stack comprising a plurality of dies.

Example 80 includes the subject matter of any of Examples 76-79, and wherein the means for providing memory is a dynamic random-access memory (DRAM) die.

Example 81 includes the subject matter of any of Examples 76-80, and wherein the means for providing memory is a static random-access memory (SRAM) die.

Example 82 includes the subject matter of any of Examples 76-81, and wherein the means for providing memory is a NAND memory die.

Example 83 includes the subject matter of any of Examples 76-82, and wherein the means for providing power comprises a magnetic inductor array.

Example 84 includes the subject matter of any of Examples 76-83, and wherein the means for providing memory or the means for providing power or both comprise die-to-die connectivity circuitry.

Example 85 includes the subject matter of any of Examples 76-84, and further including one or more copper pillars next to the means for providing power, the one or more copper pillars extending from the means for providing memory to a plane defined by a surface of the substrate core.

Example 86 includes the subject matter of any of Examples 76-85, and wherein a bottom surface of the means for providing power is within 100 micrometers of a plane defined by a bottom surface of the substrate core, wherein a top surface of the means for providing power is within 100 micrometers of a plane defined by a top surface of the substrate core.

Example 87 includes the subject matter of any of Examples 76-86, and wherein the substrate core has a thickness of at least 800 micrometers.

Example 88 includes the subject matter of any of Examples 76-87, and wherein the substrate core has a thickness less than 200 micrometers.

Example 89 includes the subject matter of any of Examples 76-88, and wherein the means for providing memory comprises a silicon die, wherein the silicon die comprises one or more through-silicon vias, wherein individual through-silicon vias of the one or more through-silicon vias extend from a top surface of the silicon die to a bottom surface of the silicon die.

Example 90 includes the subject matter of any of Examples 76-89, and wherein the means for providing power comprises a silicon die, wherein the silicon die comprises one or more through-silicon vias, wherein individual through-silicon vias of the one or more through-silicon vias extend from a top surface of the silicon die to a bottom surface of the silicon die.

Example 91 includes the subject matter of any of Examples 76-90, and further including a semiconductor die disposed on a surface of a circuit board of the apparatus, wherein the semiconductor die is positioned at least partially above the means for providing power.

Example 92 includes the subject matter of any of Examples 76-91, and further including a second semiconductor die disposed on a second surface of the circuit board, the second surface opposite the surface, wherein the second semiconductor die is positioned at least partially below the means for providing power.

Example 93 includes the subject matter of any of Examples 76-92, and further including a fully-integrated voltage regulator (FIVR), wherein the FIVR comprises the means for providing power.

Example 94 includes the subject matter of any of Examples 76-93, and further including a plurality of build-up layers adjacent the substrate core.

Example 95 includes a method comprising forming a cavity in a substrate core; disposing a power component and a memory component in the cavity, wherein the memory component is disposed above or below the power component; and filling the cavity with a filler material.

Example 96 includes the subject matter of Example 95, and further including forming a plurality of power components on a semiconductor wafer; thinning the semiconductor wafer; and dicing the semiconductor wafer to form the power component.

Example 97 includes the subject matter of any of Examples 95 and 96, and further including forming a plurality of power components on a semiconductor wafer; dicing the semiconductor wafer to form the power component; and thinning the power component after dicing of the semiconductor wafer and before disposing the power component in the cavity.

Example 98 includes the subject matter of any of Examples 95-97, and wherein disposing the power component and the memory component in the cavity comprises disposing the power component in the cavity; depositing die attach film on the power component in the cavity; and disposing the memory component on the die attach film.

Example 99 includes the subject matter of any of Examples 95-98, and further including forming a first plurality of power components on a first semiconductor wafer; forming second plurality of power components on a second semiconductor wafer; bonding the first semiconductor wafer and the second semiconductor wafer, wherein bonding the first semiconductor wafer and the second semiconductor wafer comprising bonding the power component and the memory component; and dicing the first semiconductor wafer and the second semiconductor wafer, wherein disposing the power component and the memory component in the cavity comprises disposing the power component and the memory component in the cavity while the power component is bonded to the memory component.

Example 100 includes the subject matter of any of Examples 95-99, and wherein disposing the power component and the memory component in the cavity comprises bonding the power component and the memory component; and disposing the power component and the memory component in the cavity while the power component is bonded to the memory component.

Example 101 includes the subject matter of any of Examples 95-100, and wherein the power component is a deep trench capacitor.

Example 102 includes the subject matter of any of Examples 95-101, and wherein the power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 103 includes the subject matter of any of Examples 95-102, and wherein the memory component is a high-bandwidth memory stack comprising a plurality of dies.

Example 104 includes the subject matter of any of Examples 95-103, and wherein the memory component is a dynamic random-access memory (DRAM) die.

Example 105 includes the subject matter of any of Examples 95-104, and wherein the memory component is a static random-access memory (SRAM) die.

Example 106 includes the subject matter of any of Examples 95-105, and wherein the memory component is a NAND memory die.

Example 107 includes the subject matter of any of Examples 95-106, and wherein the power component is a magnetic inductor array.

Example 108 includes the subject matter of any of Examples 95-107, and wherein the memory component or the power component or both comprise die-to-die connectivity circuitry.

Example 109 includes the subject matter of any of Examples 95-108, and further including one or more copper pillars next to the power component, the one or more copper pillars extending from the memory component to a plane defined by a surface of the substrate core.

Example 110 includes the subject matter of any of Examples 95-109, and wherein a bottom surface of the power component is within 100 micrometers of a plane defined by a bottom surface of the substrate core, wherein a top surface of the memory component is within 100 micrometers of a plane defined by a top surface of the substrate core.

Example 111 includes the subject matter of any of Examples 95-110, and wherein the substrate core has a thickness of at least 800 micrometers.

Example 112 includes the subject matter of any of Examples 95-111, and wherein a difference between a thickness of the power component and a thickness of the memory component is less than five micrometers.

Example 113 includes the subject matter of any of Examples 95-112, and wherein a difference between a thickness of the power component and a thickness of the memory component is at least 20 micrometers.

Example 114 includes the subject matter of any of Examples 95-113, and wherein the substrate core has a thickness less than 200 micrometers.

Example 115 includes the subject matter of any of Examples 95-114, and wherein the power component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the memory component.

Example 116 includes the subject matter of any of Examples 95-115, and wherein the memory component comprises a silicon die, wherein the silicon die comprises one or more through-silicon vias, wherein individual through-silicon vias of the one or more through-silicon vias extend from a top surface of the silicon die to a bottom surface of the silicon die, wherein individual through-silicon vias of the one or more through-silicon vias are connected to the power component.

Example 117 includes the subject matter of any of Examples 95-116, and further including disposing a semiconductor die on a surface of a circuit board of the apparatus, wherein the semiconductor die is positioned at least partially above the power component and the memory component.

Example 118 includes the subject matter of any of Examples 95-117, and further including disposing a second semiconductor die on a second surface of the circuit board, the second surface opposite the surface, wherein the second semiconductor die is positioned at least partially below the power component and the memory component.

Example 119 includes the subject matter of any of Examples 95-118, and wherein an integrated circuit component comprising the circuit board and the semiconductor die further comprise a fully-integrated voltage regulator (FIVR), wherein the FIVR comprises the power component.

Example 120 includes the subject matter of any of Examples 95-119, and further including disposing a second power component above the power component and next to the memory component.

Example 121 includes the subject matter of any of Examples 95-120, and further including disposing a second power component in the cavity; and disposing a second memory component in the cavity, wherein the second memory component is disposed above or below the second power component.

Example 122 includes the subject matter of any of Examples 95-121, and further including forming a second cavity in the substrate core, the second cavity separate from the cavity; disposing a second power component in the second cavity; and disposing a second memory component in the second cavity, wherein the second memory component is disposed above or below the second power component.

Example 123 includes the subject matter of any of Examples 95-122, and further including forming a plurality of buildup layers adjacent the substrate core.

1. An apparatus comprising:
a substrate core, wherein a cavity is defined in the substrate core;
a first die disposed in the cavity, the first die comprising a capacitor; and
a second die disposed in the cavity, wherein the second die is a memory die, wherein the second die is disposed above or below the first die.

2. The apparatus of claim 1, wherein the first die is a deep trench capacitor die.

3. The apparatus of claim 1, wherein the second die is part of a high-bandwidth memory stack comprising a plurality of dies.

4. The apparatus of claim 1, wherein the second die is a dynamic random-access memory (DRAM) die.

5. The apparatus of claim 1, wherein the second die is a static random-access memory (SRAM) die.

6. The apparatus of claim 1, wherein the second die is a NAND memory die.

7. The apparatus of claim 1, wherein the first die comprises a magnetic inductor array.

8. The apparatus of claim 1, wherein the second die or the first die or both comprise die-to-die connectivity circuitry.

9. The apparatus of claim 1, further comprising one or more copper pillars next to the first die, the one or more copper pillars extending from the second die to a plane defined by a surface of the substrate core.

10. The apparatus of claim 1, wherein the substrate core has a thickness of at least 800 micrometers.

11. The apparatus of claim 1, further comprising a third die disposed on a surface of a circuit board of the apparatus, wherein the third die is positioned at least partially above the first die and the second die.

12. The apparatus of claim 11, further comprising a fully-integrated voltage regulator (FIVR), wherein the FIVR comprises the first die.

13. An apparatus comprising:
a circuit board;
a semiconductor die; and
a component stack disposed in the circuit board, wherein the component stack comprises a power component and a memory component.

14. The apparatus of claim 13, wherein the power component is a deep trench capacitor.

15. The apparatus of claim 14, wherein the power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

16. The apparatus of claim 13, wherein the memory component is a high-bandwidth memory stack comprising a plurality of dies.

17. The apparatus of claim 13, wherein the memory component or the power component or both comprise die-to-die connectivity circuitry.

18. A method comprising:
forming a cavity in a substrate core;
disposing a power component and a memory component in the cavity, wherein the memory component is disposed above or below the power component; and
filling the cavity with a filler material.

19. The method of claim 18, wherein disposing the power component and the memory component in the cavity comprises:
disposing the power component in the cavity;
depositing die attach film on the power component in the cavity; and
disposing the memory component on the die attach film.

20. The method of claim 18, further comprising:
forming a first plurality of power components on a first semiconductor wafer;
forming second plurality of power components on a second semiconductor wafer;
bonding the first semiconductor wafer and the second semiconductor wafer, wherein bonding the first semiconductor wafer and the second semiconductor wafer comprising bonding the power component and the memory component; and
dicing the first semiconductor wafer and the second semiconductor wafer,
wherein disposing the power component and the memory component in the cavity comprises disposing the power component and the memory component in the cavity while the power component is bonded to the memory component.
